(19) United States
(12) Patent Application Publication
(10) Pub. No.: US 2023/0374655 A1
(43) Pub. Date: Nov. 23, 2023

(54) MASK ASSEMBLY AND MASK REPLACEMENT METHOD

(71) Applicant: Samsung Display Co., Ltd., Yongin-si (KR)

(72) Inventors: JEONGKUK KIM, Yongin-si (KR); SEUNGYONG SONG, Yongin-si (KR); WONJE CHO, Yongin-si (KR); EUNBEE JO, Yongin-si (KR); KYU HWAN HWANG, Yongin-si (KR)

(73) Assignee: Samsung Display Co., Ltd., Yongin-si (KR)

(21) Appl. No.: 18/125,178

(22) Filed: Mar. 23, 2023

(30) Foreign Application Priority Data
May 20, 2022 (KR) 10-2022-0062319

(51) Int. Cl. C23C 16/04

(52) U.S. Cl. CPC C23C 16/042; H10K 59/12

(57) ABSTRACT

A mask replacement method includes providing the mask assembly including a frame including an opening, a first mask disposed on the frame, and first welding portions overlapping the first mask in a plan view, removing the first mask from the frame, and forming a second mask and second welding portions overlapping the second mask in a plan view on the frame on which the first welding portions are disposed. The first welding portions may be spaced apart from the second mask, and the first welding portions and the second welding portions may be arranged in a direction.

### CROSS-REFERENCE TO RELATED APPLICATION

This application claims priority to and benefits of Korean Patent Application No. 10-2022-0062319 under 35 U.S.C. § 119, filed in the Korean Intellectual Property Office (KIPO) on May 20, 2022, the entire contents of which are incorporated herein by reference.

### BACKGROUND

### 1. Technical Field

The disclosure herein relates to a mask assembly including a mask and a method for replacing the mask of the mask assembly.

### 2. Description of the Related Art

Display devices such as a television, a mobile phone, a tablet computer, a navigation system, and a game machine may include a display panel configured to display an image. The display panel may include pixels composed of a driving element such as a transistor and a display element such as an organic light-emitting diode. A display device may be formed by depositing an electrode, a functional layer, and a light-emitting pattern on a substrate with the use of a mask assembly.

The mask assembly may include a frame and a mask, or may further include a mask part. When the mask is damaged or the reliability thereof is deteriorated in the process of mass-producing the display panel, the replacement of the mask may be required. When the mask is replaced, however, there is a limit on reusing the frame to which the mask is coupled. Therefore, when the mask is replaced, a high cost may be required for a mask replacement due to the cost of manufacturing a new frame.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

The disclosure provides a mask and a frame which may be reused in case that the mask is replaced.

The disclosure also provides a mask replacement method for reducing replacement costs in case that the mask of a mask assembly is replaced.

However, embodiments of the disclosure are not limited to those set forth herein. The above and other embodiments will become more apparent to one of ordinary skill in the art to which the disclosure pertains by referencing the detailed description of the disclosure given below.

An embodiment of the disclosure provides a mask replacement method including providing a mask assembly including a frame including an opening, a first mask disposed on the frame, and first welding portions overlapping the first mask in a plan view; removing the first mask from the frame; and forming a second mask and second welding portions overlapping the second mask in a plan view on the frame on which the first welding portions are disposed. The first welding portions may be spaced apart from the second mask. The first welding portions and the second welding portions are arranged in a direction.

In an embodiment, the providing of the mask assembly may include providing, on the frame, a first preliminary mask including a first deposition portion overlapping the opening in a plan view, a plurality of first coupling portions protruding from the first deposition portion, and a plurality of first non-coupling portions protruding from the first deposition portion; forming the first welding portions in the plurality of first coupling portions to couple the plurality of first coupling portions and the frame to each other; and removing the plurality of first non-coupling portions from the first preliminary mask to form the first mask.

In an embodiment, the plurality of first coupling portions may be spaced apart from each other in the direction, and at least one of the plurality of first non-coupling portions is disposed between adjacent ones of the plurality of first coupling portions in a plan view.

In an embodiment, the providing of the first preliminary mask may include providing a first initial preliminary mask including the first deposition portion and a first non-deposition portion surrounding the first deposition portion; and forming first cutting portions passing through the first initial preliminary mask in the first non-deposition portion to form the first preliminary mask. The first cutting portions may be spaced apart from each other in a first direction and a second direction intersecting the first direction in a plan view, and regions between the first cutting portions may respectively correspond to the plurality of first coupling portions and the plurality of first non-coupling portions.

In an embodiment, a distance between the first cutting portions may be about 2 mm or more.

In an embodiment, each of the first cutting portions may extend to an outer edge of the first initial preliminary mask.

In an embodiment, each of the first cutting portions may be surrounded by the first non-deposition portion.

In an embodiment, the providing of the first preliminary mask may further include cutting at least a portion of the first preliminary mask along a first trimming line defined on the first preliminary mask. The first trimming line may correspond to a virtual line connecting inner side surfaces of the first cutting portions adjacent to an outer edge of the first preliminary mask.

In an embodiment, the frame may further include a first recessed portion recessed from an upper surface on which the first preliminary mask is disposed. The first recessed portion may overlap the first trimming line in a plan view.

In an embodiment, the frame may further include a second recessed portion recessed from an upper surface on which the first preliminary mask is disposed. The removing of the plurality of first non-coupling portions may include irradiating a beam onto the first non-coupling portions overlapping the second recessed portion in a plan view.

In an embodiment, the forming of the second mask and the second welding portions may include providing, on the frame, a second preliminary mask including a second deposition portion overlapping the opening in a plan view, a plurality of second coupling portions protruding from the second deposition portion, and a plurality of second non-coupling portions protruding from the second deposition portion; forming the second welding portions on the plurality of second coupling portions to couple the plurality of second coupling portions and the frame to each other; and removing the plurality of second non-coupling portions from the second preliminary mask to form the second mask. The plurality of second coupling portions may respectively non-overlap the first welding portions in a plan view.

In an embodiment, the forming of the second mask may include providing a second preliminary mask. The second mask may be formed from the second preliminary mask. The providing of the second preliminary mask may include providing a second initial preliminary mask; and forming second cutting portions on the second initial preliminary mask. The first initial preliminary mask and the second initial preliminary mask have same area and shape. The first cutting portions and the second cutting portions have same position and size.

In an embodiment, each of the first welding portions and the second welding portions may contain a metal oxide.

In an embodiment, the mask replacement method may further include removing the second mask from the frame; polishing the frame to remove the first welding portions and the second welding portions remaining on the frame; and forming a third mask and third welding portions overlapping the third mask on the frame in a plan view.

In an embodiment of the disclosure, a mask assembly includes a frame including an upper surface, a lower surface opposite to the upper surface, and an opening passing through from the upper surface to the lower surface; a mask disposed on the frame; first welding portions disposed on the frame, and second welding portions disposed on the frame. The mask includes a deposition portion overlapping the opening in a plan view; and a plurality of coupling portions protruding from the deposition portion and overlapping the frame in a plan view. The second welding portions may respectively overlap the plurality of coupling portions in a plan view, and each of the first welding portions may be spaced apart from the mask.

In an embodiment, each of the frame and the mask may contain a metal, and each of the first and second welding portions may contain a metal oxide.

In an embodiment, the plurality of coupling portions may be spaced apart from each other in a first direction and a second direction intersecting the first direction in a plan view. The first welding portions may be disposed between the plurality of coupling portions spaced apart from each other.

In an embodiment, the first welding portions and the second welding portions may be arranged in the first direction and the second direction in a plan view.

In an embodiment, the frame may further include a first recessed portion recessed from the upper surface and a second recessed portion recessed from the upper surface. In a plan view, the first recessed portion may overlap ends of the deposition portion exposed from the plurality of coupling portions. The second recessed portion may overlap ends of the plurality of coupling portions in a plan view.

In an embodiment of the disclosure, a mask assembly includes a frame including an upper surface, a lower surface opposite to the upper surface, an opening passing through from the upper surface to the lower surface, a first recessed portion recessed from the upper surface, and a second recessed portion recessed from the upper surface; a mask disposed on the frame; and welding portions disposed on the frame. The mask may include a deposition portion overlapping the opening in a plan view; and a plurality of coupling portions protruding from the deposition portion and overlapping the frame in a plan view. At least some of the welding portions may overlap the mask in a plan view. The first recessed portion may overlap ends of the deposition portion exposed from the plurality of coupling portions in a plan view. The second recessed portion may overlap ends of the plurality of coupling portions in a plan view.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic cross-sectional view of a deposition apparatus according to an embodiment of the disclosure;

FIG. 2 is a schematic cross-sectional view of a display panel according to an embodiment of the disclosure;

FIGS. 3A and 3B are schematic flowcharts of a mask replacement method according to an embodiment of the disclosure;

FIG. 4A is a schematic plan view corresponding to a step of the mask replacement method according to an embodiment of the disclosure;

FIG. 4B is a schematic enlarged plan view of area AA of FIG. 4A;

FIG. 5 is a schematic plan view corresponding to a step of the mask replacement method according to an embodiment of the disclosure;

FIGS. 6A and 6B are schematic plan views corresponding to a step of the mask replacement method according to an embodiment of the disclosure;

FIG. 7 is a schematic plan view of a mask assembly according to an embodiment of the disclosure;

FIGS. 8 to 10 are schematic plan views corresponding to a step of the mask replacement method according to an embodiment of the disclosure;

FIG. 11A is a schematic plan view of a mask assembly according to an embodiment of the disclosure;

FIG. 11B is a schematic cross-sectional view of the mask assembly, which corresponds to line I-I′ of FIG. 11A, according to an embodiment of the disclosure;

FIG. 12 is a schematic plan view of the mask assembly according to an embodiment of the disclosure;

FIGS. 13A and 13B are schematic plan views corresponding to a step of the mask replacement method according to an embodiment of the disclosure;

FIG. 14 is a schematic plan view corresponding to a step of the mask replacement method according to an embodiment of the disclosure;

FIGS. 15A to 15D are schematic cross-sectional views corresponding to line II-II′ of FIG. 14 and illustrating a step of the mask replacement method according to an embodiment of the disclosure;

FIGS. 16A to 16D are schematic cross-sectional views corresponding to line II-II′ of FIG. 14 and illustrating a step of the mask replacement method according to an embodiment of the disclosure;

FIG. 16E is a schematic plan view of a mask assembly according to an embodiment of the disclosure; and

FIGS. 17A to 17C are schematic cross-sectional views corresponding to line II-II′ of FIG. 14 and illustrating a step of the mask replacement method according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

When an element, such as a layer, is referred to as being “on,” “connected to,” or “coupled to” another element or layer, it may be directly on, connected, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. It may also be understood that if one part and another part are connected, they may or may not be integral with each other.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Although the terms “first,” “second,” and the like may be used herein to describe various elements, these elements should not be limited by these terms. These terms are used to distinguish one element from another elements. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, a mask assembly and a mask replacement method of the mask assembly according to an embodiment of the disclosure are described with reference to the drawings.

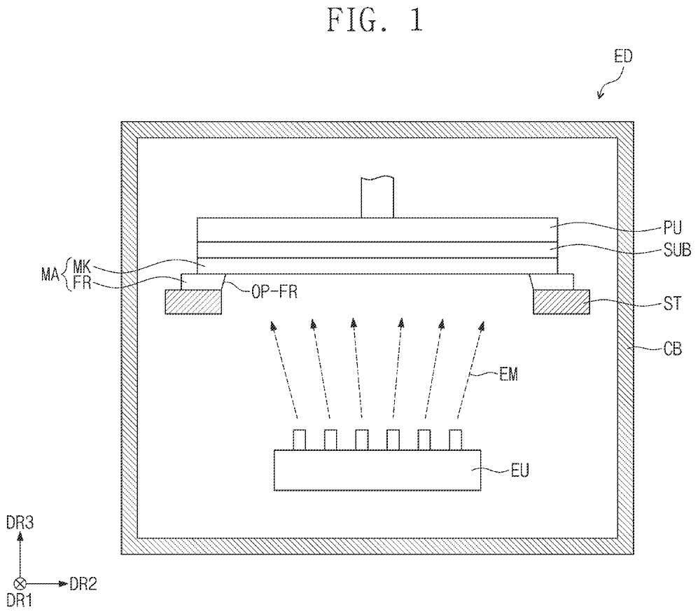

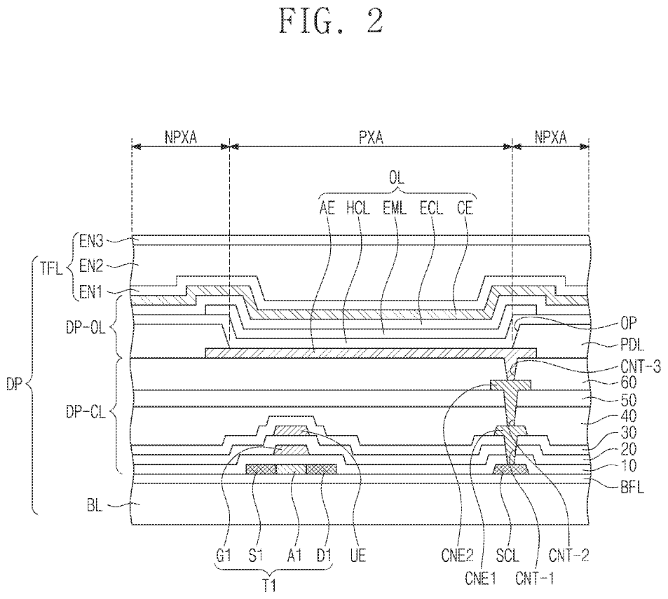

FIG. 1 is a schematic cross-sectional view of a deposition apparatus according to an embodiment of the disclosure. FIG. 2 is a schematic cross-sectional view of a display panel according to an embodiment of the disclosure.

Referring to FIG. 1, the deposition apparatus ED may include a chamber CB, a deposition part EU, a fixing part PU, a stage ST, and a mask assembly MA. The deposition apparatus ED according to an embodiment of the disclosure may further include an additional mechanical device for implementing an inline system.

The chamber CB may provide an internal space, and include a bottom surface, a ceiling surface, and sidewalls connecting (or extending between) the bottom surface and the ceiling surface to each other. The deposition part EU, the fixing part PU, the stage ST, and the mask assembly MA may be disposed in the internal space of the chamber CB. The chamber CB may form a closed space, and the deposition condition thereof may be set to vacuum. The chamber CB may include at least one gate, and the chamber CB may be opened and closed by the gate. The mask assembly MA and the substrate SUB may enter and exit through the gate provided in the chamber CB.

The bottom surface of the chamber CB may be parallel to a plane defined by a first direction DR1 and a second direction DR2, and a normal direction of the bottom surface of the chamber CB may be parallel to a third direction DR3. In the specification, the expression “in a plan view” is set based on a plane parallel to the plane defined by the first direction DR1 and the second direction DR2.

The fixing part PU may be disposed on the deposition part EU inside the chamber CB. The fixing part PU may fix the mask assembly MA. For example, the fixing part PU according to an embodiment of the disclosure may include a jig or a robot arm configured to hold the mask assembly MA. The fixing part PU may include a magnetic substance for closely contacting (or fixing) the mask assembly MA to the substrate SUB. For example, the magnetic substance of the fixing part PU may generate a magnetic force and apply an attractive force to the mask assembly MA. Accordingly, the substrate SUB disposed between the mask assembly MA and the fixing part PU may be closely adhered (or attracted) to the mask assembly MA.

The substrate SUB may be a to-be-processed object on which a deposition material EM is deposited. For example, the substrate SUB may include a support substrate and a synthetic resin layer disposed on the support substrate. In a second half of a manufacturing process of a display panel DP (e.g., refer to FIG. 2), the support substrate may be removed, and the synthetic resin layer may correspond to a base layer BL (e.g., refer to FIG. 2) to be described below. According to a configuration formed by using a deposition process, the substrate SUB may include some components of the display panel DP (e.g., refer to FIG. 2) disposed on the base layer BL (e.g., refer to FIG. 2).

The deposition part EU may face the fixing part PU inside the chamber CB. The deposition part EU may include a space accommodating the deposition material EM and at least one nozzle configured to spray the deposition material EM. The deposition material EM may contain at least one of an organic material, a metal, and an inorganic material which may be sublimated or vaporized. The deposition material EM may pass through the mask assembly MA and be deposited on the substrate SUB in a pattern (e.g., a predetermined or selectable pattern).

The mask assembly MA may include a mask MK and a frame FR. The mask MK may be disposed on the frame FR and coupled to the frame FR.

The mask MK may include deposition openings defining a deposition region. The mask MK according to an embodiment of the disclosure may be provided as an open mask. In an embodiment of the disclosure, multiple display panels DP (e.g., refer to FIG. 2) may correspond to a substrate SUB, and the deposition openings of the mask MK may respectively correspond to the display panels DP (e.g., refer to FIG. 2) which are formed from the substrate SUB. However, the embodiment of the disclosure is not limited thereto, and the mask assembly MA may further include a mask part disposed on the mask MK according to a configuration to be formed on the substrate SUB through a deposition.

The frame FR may support a rear surface of the mask MK parallel to the first direction DR1 and the second direction DR2. The frame FR may include an opening OP-FR (hereinafter, referred to as a frame opening OP-FR) overlapping the deposition openings of the mask MK (e.g., in a view or direction). In a plan view, the frame FR may have a closed line shape surrounding the frame opening OP-FR.

The stage ST may be disposed between the deposition part EU and the fixed part PU. The stage ST may support a rear surface of the frame FR and be disposed outside a movement path of the deposition material EM supplied from the deposition part EU to the substrate SUB.

The stage ST may provide a mounting surface on which the frame FR is mounted. The mounting surface of the stage ST may be parallel to the first direction DR1 and the second direction DR2. According to an embodiment of the disclosure, the mounting surface of the stage ST may be parallel to the bottom surface of the chamber CB, and a horizontal deposition process may be performed. However, the embodiment of the disclosure is not limited thereto, and the mounting surface of the stage ST may be perpendicular to the bottom surface of the chamber CB, and a vertical deposition process may be performed.

The deposition apparatus ED according to an embodiment of the disclosure may be used to form at least some of functional layers included in the display panel DP (e.g., refer to FIG. 2) to be described below. FIG. 2 schematically illustrates as an example the cross-sectional view of the display panel DP which is manufactured by using the deposition apparatus ED, and hereafter, an embodiment of the display panel DP is described with reference to FIG. 2.

In this embodiment, the display panel DP may be a light-emitting display panel. For example, the display panel DP may be an organic light-emitting display panel, an inorganic light-emitting display panel, or a quantum dot light-emitting display panel. A light-emitting layer of the organic light-emitting display panel may contain an organic light-emitting material, and the light-emitting layer of the inorganic light-emitting display panel may contain an inorganic light-emitting material. A light-emitting layer of the quantum dot light-emitting display panel may contain quantum dots and quantum rods. Hereinafter, the display panel DP is described as an organic light-emitting display panel.

The display panel DP may include multiple pixels. Each of the pixels may include at least one transistor and a light-emitting element. FIG. 2 schematically illustrates a region in which a transistor T1 and a light-emitting element OL among the pixels of the display panel DP are disposed.

Referring to FIG. 2, the display panel DP may include a base layer BL, a circuit element layer DP-CL, a display element layer DP-OL, and an encapsulation layer TFL.

The base layer BL may provide a base surface on which the circuit element layer DP-CL is disposed. The base layer BL may include a synthetic resin layer. For example, a synthetic resin layer may be formed on the support substrate in manufacturing the display panel DP, and a conductive layer, an insulating layer, and the like constituting the display panel DP may be formed on the synthetic resin layer. The support substrate may be removed (or omitted), and the synthetic resin layer, from which the support substrate is removed, may correspond to the base layer BL.

At least one inorganic layer may be disposed on an upper surface of the base layer BL. The inorganic layer may constitute a barrier layer and/or a buffer layer. FIG. 2 schematically illustrates the buffer layer BFL disposed on the base layer BL. The buffer layer BFL may improve a coupling force (or adhesiveness) between the base layer BL and the semiconductor pattern of the circuit element layer DP-CL.

The circuit element layer DP-CL may be disposed on the buffer layer BFL. The circuit element layer DP-CL may include at least one an insulating layer, a signal line, a circuit element, and the like which form a driving circuit of a pixel. After an insulating layer, a semiconductor layer, and a conductive layer are formed by coating, deposition, etc., the insulating layer, the semiconductor layer, and the conductive layer may be patterned through a photolithography process to form the circuit element layer DP-CL.

In this embodiment, the circuit element layer DP-CL may include a transistor T1, a connection signal line SCL, connection electrodes CNE1 and CNE2, and insulating layers 10 to 60. The insulating layers 10 to 60 may include a first insulating layer 10, a second insulating layer 20, a third insulating layer 30, a fourth insulating layer 40, a fifth insulating layer 50, and a sixth insulating layer 60 sequentially stacked one another on the buffer layer BFL. Each of the first to sixth insulating layers 10 to 60 may include at least one of an inorganic layer or an organic layer.

The transistor T1 may include a semiconductor pattern and a gate electrode G1. The semiconductor pattern may include a source region S1, an active region A1, and a drain region D1. The gate electrode G1 may be disposed on the semiconductor pattern. The semiconductor pattern of the transistor T1 may contain polysilicon. However, the embodiment of the disclosure is not limited thereto, and the semiconductor pattern may contain amorphous silicon or a metal oxide.

The semiconductor pattern may be divided into regions according to conductivity. For example, the semiconductor pattern may have different electrical properties depending on whether the semiconductor pattern is doped or the metal oxide thereof is reduced. A region having high conductivity in the semiconductor pattern may serve as an electrode or a signal line, which may correspond to the source region S1 and the drain region D1 of the transistor T1. A non-doped or non-reduced region having relatively low conductivity may correspond to the active region A1 (or the channel region) of the transistor T1.

The connection signal line SCL may be formed from the semiconductor pattern. The connection signal line SCL, the source region S1, the active region A1, and the drain region D1 of the transistor T1 may be disposed on a same layer. According to an embodiment of the disclosure, the connection signal line SCL may be electrically connected to the drain region D1 of the transistor T1 in a plan view.

The first insulating layer 10 may cover the semiconductor pattern of the transistor T1. The gate electrode G1 may be disposed on the first insulating layer 10. The gate electrode G1 may overlap the active region A1. The gate electrode G1 may function as a mask in the process of the doping of the semiconductor pattern. An upper electrode UE may be disposed on the second insulating layer 20. The upper electrode UE may overlap the gate electrode G1.

The first connection electrode CNE1 and the second connection electrode CNE2 may be disposed between the transistor T1 and the light-emitting element OL and electrically connect the transistor T1 and the light-emitting element OL to each other. The first connection electrode CNE1 may be disposed on the third insulating layer 30 and be electrically connected to the connection signal line SCL through a contact hole CNT-1 passing through the first to third insulating layers 10 to 30. The second connection electrode CNE2 may be disposed on the fifth insulating layer 50 and be electrically connected to the first connection electrode CNE1 through a contact hole CNT-2 passing through the fourth and fifth insulating layers 40 and 50.

The display element layer DP-OL may be disposed on the circuit element layer DP-CL. The display element layer DP-OL may include the light-emitting element OL and a pixel defining film PDL. The light-emitting element OL may include a first electrode AE, a hole control layer HCL, a light-emitting layer EML, an electron control layer ECL, and a second electrode CE.

The first electrode AE and the pixel defining film PDL may be disposed on the sixth insulating layer 60. The first electrode AE may be electrically connected to the second connection electrode CNE2 through a contact hole CNT-3 passing through the sixth insulating layer 60. The pixel defining film PDL may have a light-emitting opening OP exposing at least a portion of the first electrode AE. The portion of the first electrode AE exposed by the light-emitting opening OP may correspond to a light-emitting region PXA. A non-light-emitting region NPXA may surround the light-emitting region PXA.

The hole control layer HCL and the electron control layer ECL may be commonly disposed in the light-emitting region PXA and the non-light-emitting region NPXA. The light-emitting layer EML may be provided in the form of a pattern corresponding to the light-emitting opening OP. The hole control layer HCL, the electron control layer ECL, and the light-emitting layer EML may be formed by the deposition apparatus ED (e.g., refer to FIG. 1) according to an embodiment of the disclosure.

The hole control layer HCL and the electron control layer ECL in the form of a film may be commonly formed in multiple pixels by using the mask MK (e.g., refer to FIG. 1) provided as an open mask. The light-emitting layer EML may have a pattern shape corresponding to each of the pixels by using a mask part (e.g., referred to as a fine metal mask (FMM)).

The encapsulation layer TFL may include thin films. The encapsulation layer TFL according to an embodiment of the disclosure may include a first film EN1, a second film EN2, and a third thin film EN3 which are sequentially stacked one another. Each of the first to third thin films EN1, EN2, and EN3 may include any one of an inorganic film and an organic film. The inorganic film may protect the light-emitting element OL from moisture and/or oxygen. The organic film may protect the light-emitting element OL from foreign substances such as dust particles. However, the configuration of the encapsulation layer TFL is not limited to the illustrated one as long as the light-emitting element OL can be protected or the light output efficiency thereof can be improved.

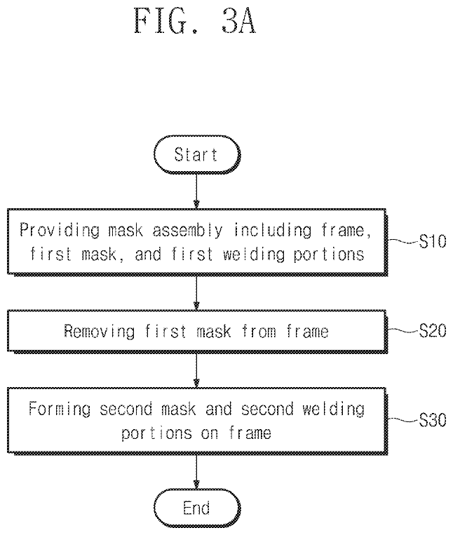

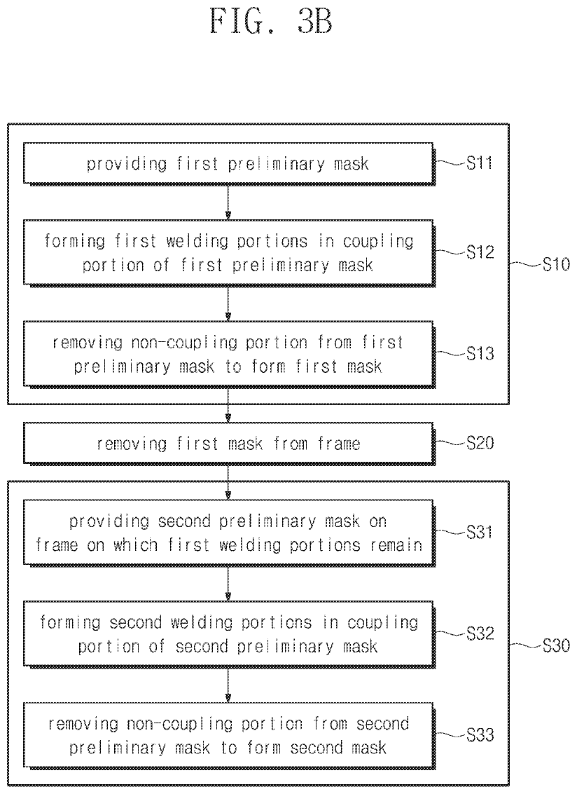

FIGS. 3A and 3B are schematic flowcharts of a mask replacement method according to an embodiment of the disclosure. Referring to FIG. 3A, the mask replacement method according to an embodiment of the disclosure may include providing a mask assembly including a frame, a first mask, and first welding portions (S10), removing the first mask from the frame (S20), and forming a second mask and second welding portions on the frame (S30).

Referring to FIG. 3B, the providing of the mask assembly (S10) according to an embodiment of the disclosure may include providing a first preliminary mask (S11) including a deposition portion, coupling portions, and non-coupling portions, forming the first welding portions in the coupling portions of the first preliminary mask (S12) so that the coupling portions are coupled to the frame, and removing the non-coupling portions from the first preliminary mask to form the first mask (S13). In the specification, the coupling portions and the non-coupling portions included in the first preliminary mask may be referred to as first coupling portions and first non-coupling portions, respectively.

Cutting portions may be formed in a sheet-shaped first initial preliminary mask including a deposition portion having a deposition opening defined therethrough and a non-deposition portion surrounding the deposition portion, and the first preliminary mask may be provided. The cutting portions may be formed in the non-deposition portion of the first initial preliminary mask. The cutting portions may be spaced apart from each other by a distance (e.g., a predetermined or selectable distance) in the non-deposition portion, and regions between the cutting portions may respectively correspond to the coupling portions and non-coupling portions of the first preliminary mask.

In the removing of the first mask from the frame (S20), after the first mask is removed, the first welding portions, which couple (or weld) the first mask and the frame to each other, may remain on the frame. In the mask replacement method according to an embodiment of the disclosure, the removing of the first welding portions remaining on the frame may be omitted and a new mask may be formed on the frame.

Referring to FIG. 3B, the forming of the second mask and the second welding portions (S30) according to an embodiment of the disclosure may include providing a second preliminary mask including a deposition portion, coupling portions, and non-coupling portions on the frame on which the first welding portions remain (S31), forming the second welding portions in the coupling portions of the second preliminary mask (S32) so that the coupling portions are coupled to the frame, and removing the non-coupling portions from the second preliminary mask to form the second mask (S33). In this specification, the coupling portions and the non-coupling portions included in the second preliminary mask may be referred to as second coupling portions and second non-coupling portions, respectively.

The second preliminary mask may be formed from a second initial preliminary mask. The second initial preliminary mask and the first initial preliminary mask may have a same area and shape. For example, cutting portions having the same position and size as the cutting portions of the first initial preliminary mask, may be formed on the second initial preliminary mask having the same area and shape as the first initial preliminary mask. Thus, the second preliminary mask may be provided. Accordingly, the second preliminary mask and the first preliminary mask may have a same area and shape.

However, the positions of the coupling portions of the second preliminary mask may be different from the positions of the coupling portions of the first preliminary mask. The coupling portions of the second preliminary mask may be spaced apart from the first welding portions formed in the coupling portions of the first preliminary mask. At least some of the non-coupling portions of the second preliminary mask may overlap the first welding portions. The non-coupling portions overlapping the first welding portions may be removed from the second preliminary mask through a subsequent process.

Hereafter, each step of the mask replacement method is described in detail with reference to the drawings corresponding to the steps of the mask replacement method.

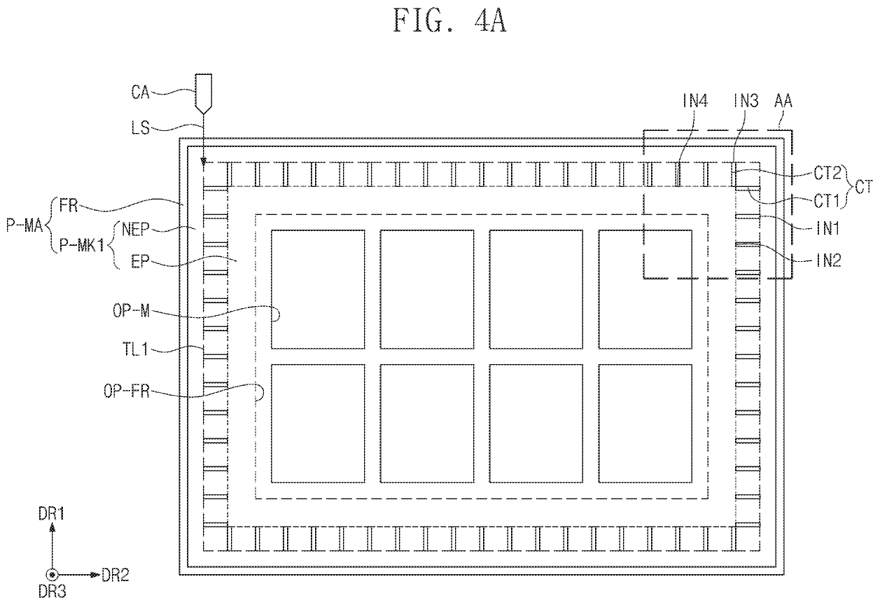

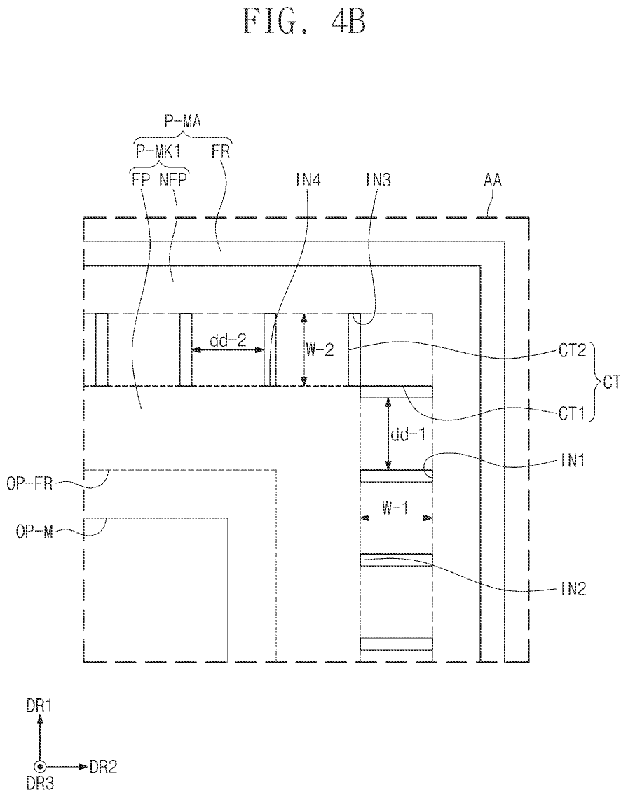

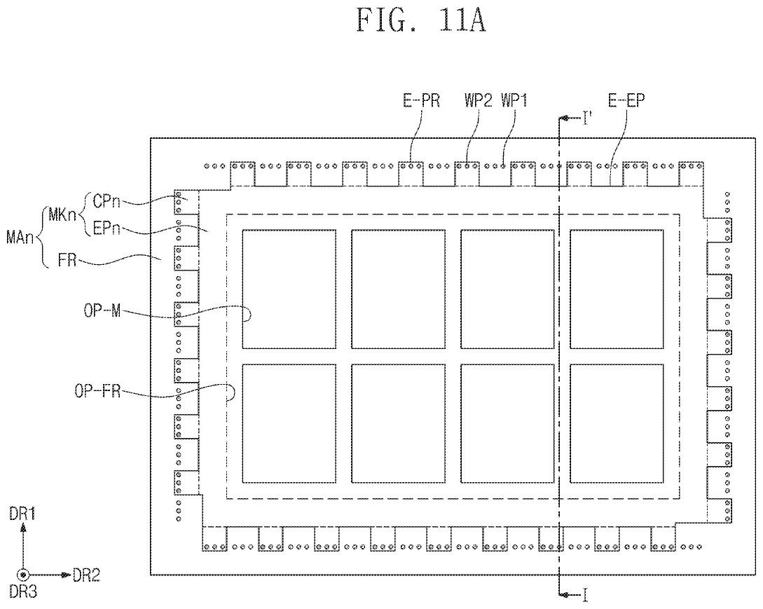

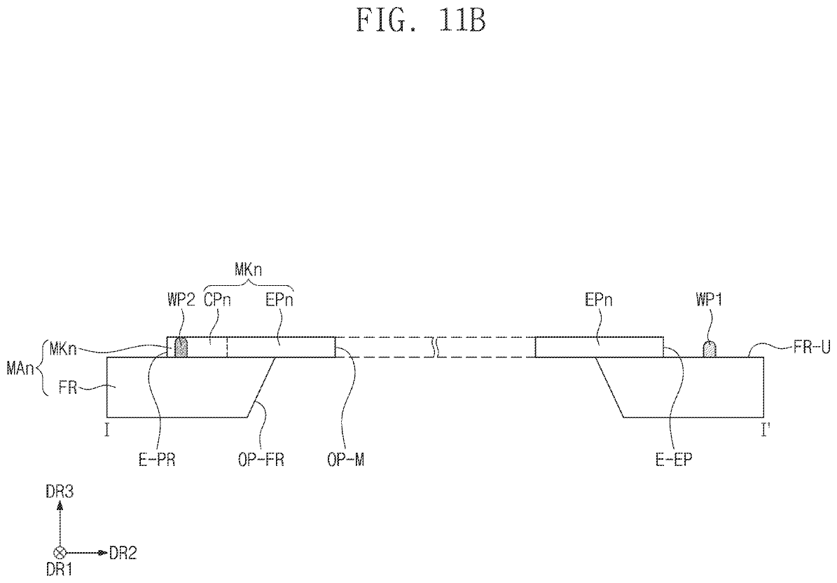

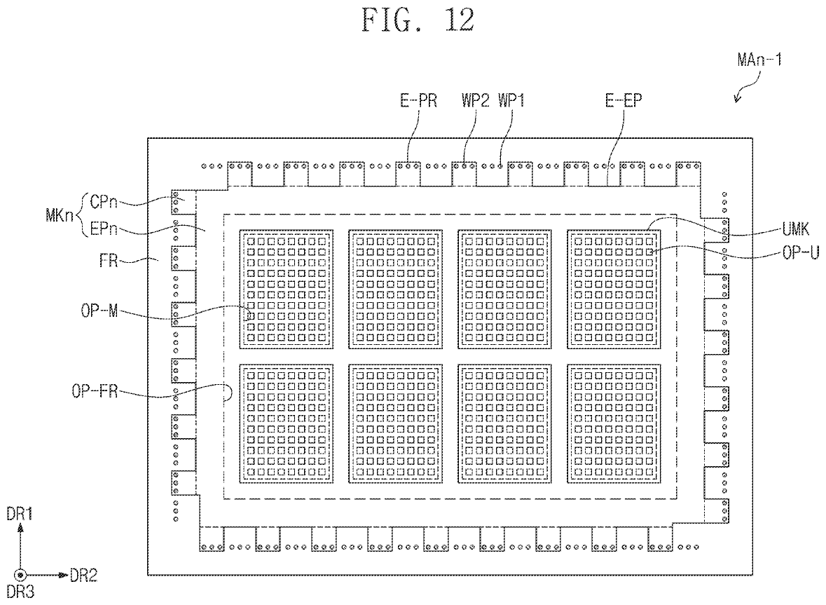

FIGS. 4A to 10 are plan views corresponding to a step of the mask replacement method according to an embodiment of the disclosure. FIGS. 11A and 12 are plan views of the mask assembly according to an embodiment of the disclosure. FIG. 11B is a cross-sectional view of the mask assembly, which corresponds to line I-F of FIG. 11A, according to an embodiment of the disclosure. The plan views briefly illustrate what is viewed from an upper surface of the frame FR.

FIG. 4A is a schematic plan view corresponding to providing a first preliminary mask P-MK1 (S11) (e.g., refer to FIG. 3B). FIG. 4B is a schematic enlarged plan view corresponding to region AA of FIG. 4A.

Referring to FIG. 4A, in the providing of the first preliminary mask P-MK1, the first preliminary mask P-MK1 may be provided on the frame FR. The frame FR may include a support surface supporting the first preliminary mask P-MK1, and the support surface may correspond to the upper surface of the frame FR. In this embodiment, the frame FR and the first preliminary mask P-MK1 provided on the frame FR may be defined as a preliminary mask assembly P-MA.

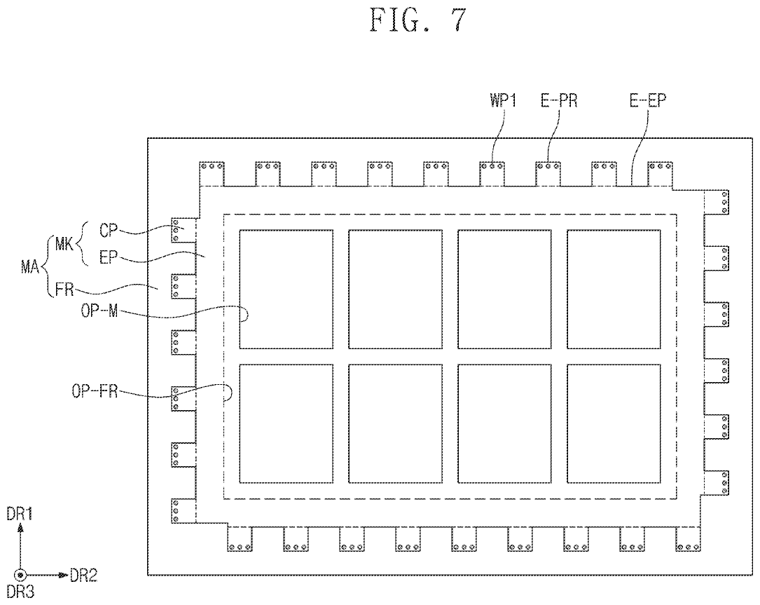

In a plan view, the frame FR may have a closed line shape defining the frame opening OP-FR. For example, the frame FR may have a quadrangular ring shape including short sides extending in the first direction DR1 and long sides extending in the second direction DR2. However, the shape of the frame FR illustrated in FIG. 4A is schematically described and is not limited to any one embodiment in case that the frame FR is capable of supporting the mask MK (e.g., refer to FIG. 7).

The frame FR may contain a material having rigidity. For example, the frame FR may contain at least one metal material of stainless steel (SUS), an invar alloy, nickel (Ni), and cobalt (Co). However, the disclosure is not limited thereto.

An outer edge of the first preliminary mask P-MK1 may include short sides extending in the first direction DR1 and long sides extending in the second direction DR2. The first preliminary mask P-MK1 may contain a metal material. For example, the first preliminary mask P-MK1 may contain at least one of stainless steel (SUS), an invar alloy, nickel (Ni), and cobalt (Co). However, the disclosure is not limited thereto.

The first preliminary mask P-MK1 may have a thickness smaller than a thickness of the frame FR. For example, the thickness of the first preliminary mask P-MK1 may be in a range of about 100 micrometers (μm) to about 200 micrometers (μm). However, the thickness of the first preliminary mask P-MK1 is not limited to the above numerical example.

In the embodiment, the first preliminary mask P-MK1 may correspond to a state in which cutting portions CT have been formed on the first initial preliminary mask provided in a sheet shape. For example, the first preliminary mask P-MK1 may correspond to a first initial preliminary mask including the cutting portions CT thereon. Detailed description of the cutting portions CT is provided below. The first preliminary mask P-MK1 may include a deposition portion EP and a non-deposition portion NEP.

In a plan view, the deposition portion EP may overlap the frame opening OP-FR. An area of the deposition portion EP may be greater than an area of the frame opening OP-FR, and accordingly, at least a portion of the deposition portion EP may overlap the frame FR in a plan view.

The deposition portion EP may be a region in which deposition openings OP-M are formed in the first preliminary mask P-MK1. The deposition openings OP-M may pass through the deposition portion EP in a region of the deposition portion EP. The deposition openings OP-M may overlap the frame opening OP-FR in a plan view.

Each of the deposition openings OP-M may have a tetragonal shape in a plan view. Each of the deposition openings OP-M may have a tetragonal shape with rounded corners. In some embodiments, each of the deposition openings OP-M may have a substantially tetragonal shape with angled corners. However, the disclosure is not limited thereto, and the shape of the deposition openings OP-M may be variously changed according to the shape of a deposition pattern desired to be formed.

The deposition openings OP-M may have an arrangement (e.g., a predetermined or selectable arrangement) in the deposition portion EP and define a deposition region of the substrate SUB (e.g., refer to FIG. 1) which is a to-be-processed object. For example, the deposition material EM (e.g., refer to FIG. 1) injected from the deposition part EU (e.g., refer to FIG. 1) may pass through the frame opening OP-FR and the deposition openings OP-M and form the deposition pattern, which corresponds to the shape and arrangement of the deposition openings OP-M, on the substrate SUB. In an embodiment of the disclosure, the deposition pattern may correspond to the hole control layer HCL (e.g., refer to FIG. 2) or the electron control layer ECL (e.g., refer to FIG. 2) of the display panel DP (e.g., refer to FIG. 2). However, the embodiment of the deposition pattern is not limited to any one layer in case that the layer is formed through deposition in the display panel DP (e.g., refer to FIG. 2).

Although FIG. 4A schematically illustrates eight deposition openings OP-M arranged in the first direction DR1 and the second direction DR2, the arrangement and number of the deposition openings OP-M included in the deposition portion EP are not limited thereto.

The non-deposition portion NEP may surround the deposition portion EP. For example, the non-deposition portion NEP may include portions extending in the first direction DR1 and/or the second direction DR2 and surrounding the deposition portion EP. In a plan view, the non-deposition portion NEP may overlap the frame FR and may not overlap the frame opening OP-FR. An outer edge of the non-deposition portion NEP may correspond to the outer edge of the first preliminary mask P-MK1.

Referring to FIGS. 4A and 4B, the non-deposition portion NEP may be a region in which the cutting portions CT are formed in the first preliminary mask P-MK1. The cutting portions CT may pass through the non-deposition portion NEP in a region of the non-deposition portion NEP. The cutting portions CT may be surrounded by the non-deposition portion NEP in a plan view. For example, the cutting portions CT may be formed within the non-deposition portion NEP in a plan view. The cutting portions CT may include first cutting portions CT1 extending in the second direction DR2 and second cutting portions CT2 extending in the first direction DR1.

The first cutting portions CT1 may be formed in at least a portion of the non-deposition portion NEP extending in the first direction DR1. The first cutting portions CT1 may be arranged in the non-deposition portion NEP in the first direction DR1. The second cutting portions CT2 may be formed in at least a portion of the non-deposition portion NEP extending in the second direction DR2. The second cutting portions CT2 may be arranged in the second direction DR2 in the non-deposition portion NEP.

Each of the first cutting portions CT1 may include first and second inner side surfaces IN1 and IN2 facing in the second direction DR2 and exposed to the outside. In the second direction DR2, the first inner side surface IN1 may be closer to the outer edge of the non-deposition portion NEP than the second inner side surface IN2.

Each of the second cutting portions CT2 may include third and fourth inner side surfaces IN3 and IN4 facing in the first direction DR1 and exposed to the outside. In the first direction DR1, the third inner side surface IN3 may be closer to the outer edge of the non-deposition portion NEP than the fourth inner side surface IN4.

Referring to FIG. 4B, the first cutting portions CT1 adjacent to each other in the first direction DR1 may be spaced apart from each other by a distance dd-1. Each of the first cutting portions CT1 may have a width W-1 in the second direction DR2.

The second cutting portions CT2 adjacent to each other in the second direction DR2 may be spaced apart from each other by a distance dd-2. Each of the second cutting portions CT2 may have a width W-2 in the first direction DR1.

In an embodiment of the disclosure, the distance dd-1 between the first cutting portions CT1 and the distance dd-2 between the second cutting portions CT2 may be substantially the same as each other, and the width W-1 of the first cutting portion CT1 and the width W-2 of the second cutting portion CT2 may be substantially the same as each other. However, the embodiment of the disclosure is not limited thereto.

In a subsequent process, a welding portion may be formed in some of the regions between the first cutting portions CT1 and the regions between the second cutting portions CT2. Accordingly, the first cutting portions CT1 may be spaced apart from each other by a distance dd-1, and the region between the first cutting portions CT1 may have an area enough to form the welding portion. The second cutting portions CT2 may be spaced apart from each other by a distance dd-2, and the region between the second cutting portions CT2 may have an area enough to form the welding portion. For example, the widths W-1 and W-2 of each of the first cutting portions CT1 and the second cutting portions CT2, the distance dd-1 between the first cutting portions CT1, and the distance dd-2 between the second cutting portions CT2 may be adjusted, and the area of the region between the first cutting portions CT1 and the area of the region between the second cutting portions CT2 may be adjusted. For example, the width W-1 of each of the first cutting portions CT1 and the width W-2 of each of the second cutting portions CT2 may be about 1 millimeter (mm) or more. Each of the distance dd-1 between the first cutting portions CT1 and the distance dd-2 between the second cutting portions CT2 may be about 2 millimeters (mm) or more.

A first trimming line TL1 may be defined in the non-deposition portion NEP. The first trimming line TL1 may be set as at least a portion of the non-deposition portion NEP which is to be cut. The first trimming line TL1 may correspond to a virtual line connecting the first inner side surfaces IN1 of the first cutting portions CT1 and the third inner side surfaces IN3 of the second cutting portions CT2 to each other. For example, the first trimming line TL1 may include a first line extending in the first direction DR1 and a second line extending in the second direction DR2. The first line may be a virtual line connecting the first inner side surfaces IN1 of the first cutting portions CT1 to each other, and the second line may be a virtual line connecting the third inner side surfaces IN3 of the second cutting portions CT2 to each other.

In the providing of the first preliminary mask P-MK1, an outer region of the first trimming line TL1 in the non-deposition portion NEP may be removed. A cutting apparatus CA may be provided on the first trimming line TL1 to irradiate a beam LS along the first trimming line TL1. For example, the cutting apparatus CA may be a heat irradiator, a light irradiator, or a laser oscillator. The cutting apparatus CA is not limited to any one embodiment as long as it can cut at least a portion of the first preliminary mask P-MK1. Hereafter, the above description may be equally applied to the cutting apparatus CA to be provided in a subsequent process.

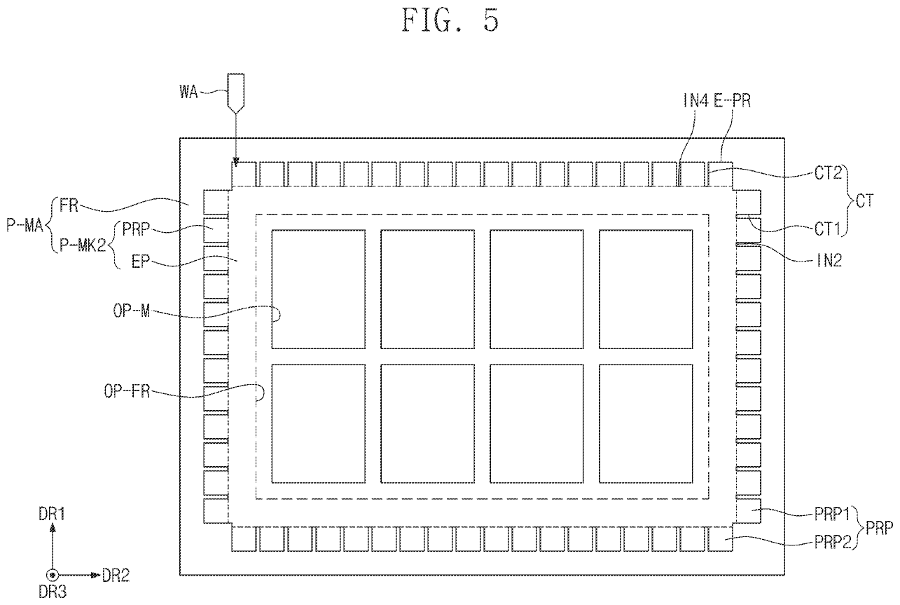

FIG. 5 corresponds to welding a first preliminary mask P-MK2 (S12) (e.g., refer to FIG. 3B). The first preliminary mask P-MK2 of FIG. 5 may correspond to a state in which the outer region of the first trimming line TL1 (e.g., refer to FIG. 4A) has been removed from the non-deposition portion NEP (e.g., refer to FIG. 4A). For example, the first preliminary mask P-MK2 of FIG. 5 may correspond to a non-deposition portion NEP without the outer region of the first trimming line TL1 (e.g., refer to FIG. 4A).

Referring to FIG. 5, the first preliminary mask P-MK2, from which the outer region of the first trimming line TL1 (e.g., refer to FIG. 4A) of the non-deposition portion NEP (e.g., refer to FIG. 4A) is removed, may include protruding portions PRP. The protruding portions PRP and the deposition portion EP may be integral with each other, and the protruding portions PRP may protrude from the deposition portion EP in a direction in a plan view.

In a plan view, the protruding portions PRP may include first protruding portions PRP1 and second protruding portions PRP2. The first protruding portions PRP1 may protrude from the deposition portion EP in a direction parallel to the second direction DR2, and the second protruding portions PRP2 may protrude from the deposition portion EP in a direction parallel to the first direction DR1. The first protruding portions PRP1 may be formed from at least a portion of the non-deposition portion NEP (e.g., refer to FIG. 4A) extending in the first direction DR1. The second protruding portions PRP2 may be formed from at least a portion of the non-deposition portion NEP (e.g., refer to FIG. 4A) extending in the second direction DR2.

The outer region of the first trimming line TL1 may be removed from the non-deposition portion NEP (e.g., refer to FIG. 4A), and ends E-PR of the first protruding portions PRP1 and ends E-PR of the second protruding portions PRP2 may be formed and exposed to the outside. The ends E-PR of the first protruding portions PRP1, the ends E-PR of the second protruding portions PRP2, the second inner side surfaces IN2, and the fourth inner side surfaces IN4 may be connected to each other and define the outer edge of the first preliminary mask P-MK2.

In a plan view, the ends E-PR of the first protruding portions PRP1 may protrude more from the deposition portion EP than the second inner side surfaces IN2 in a direction parallel to the second direction DR2. In a plan view, the ends E-PR of the second protruding portions PRP2 may protrude more from the deposition portion EP than the fourth inner side surfaces IN4 in a direction parallel to the first direction DR1.

The first protruding portions PRP1 adjacent to each other in the first direction DR1 may be spaced apart from each other with the first cutting portion CT1 disposed therebetween. The second protruding portions PRP2 adjacent to each other in the second direction DR2 may be spaced apart from each other with the second cutting portion CT2 disposed therebetween.

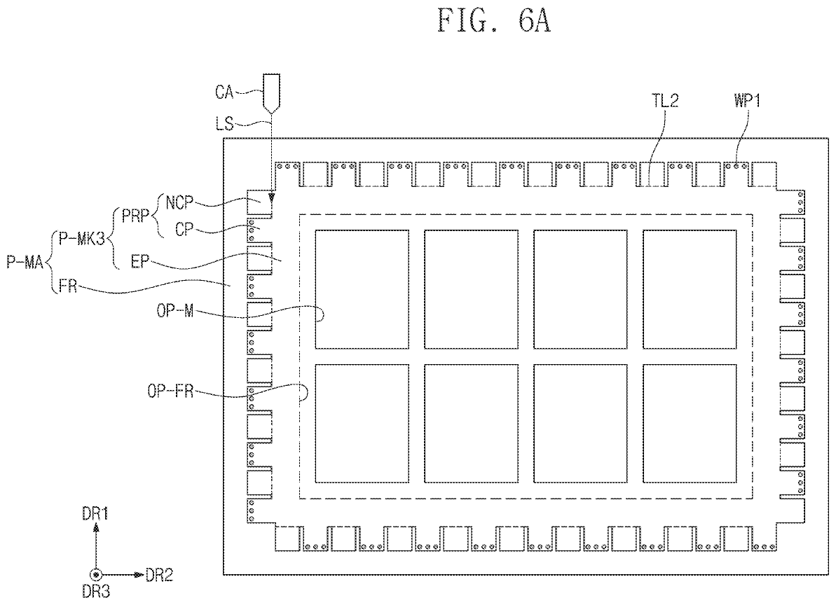

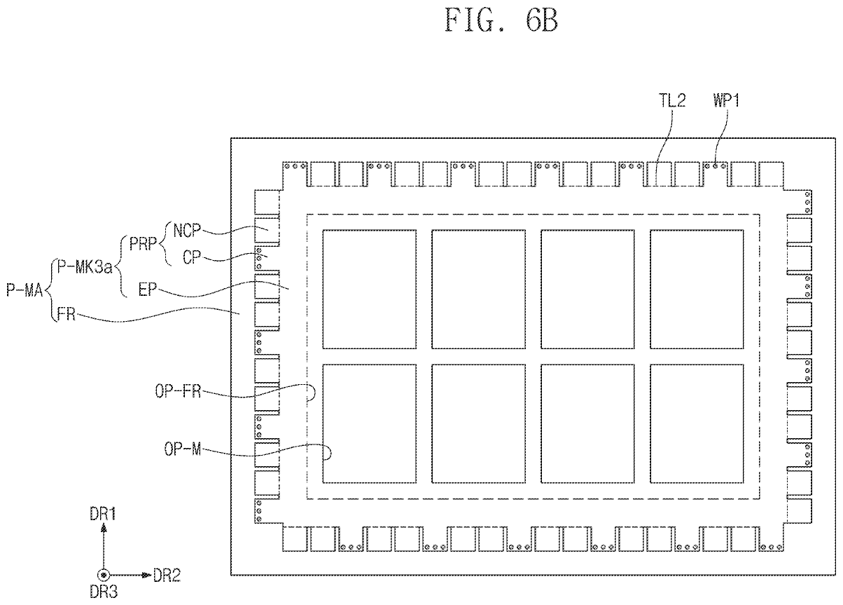

In the welding of the first preliminary mask P-MK2, some of the first protruding portions PRP1 and the second protruding portions PRP2 may be welded to the frame FR to form first welding portions WP1 (e.g., refer to FIGS. 6A and 6B). Each of the first protruding portions PRP1 and the second protruding portions PRP2 may include a coupling portion CP (e.g., refer to FIGS. 6A and 6B) or a non-coupling portion NCP (e.g., refer to FIGS. 6A and 6B).

For example, the portions (e.g., welding portions), which are welded among the first protruding portions PRP1 and the second protruding portions PRP2, may correspond to the coupling portions CP (e.g., refer to FIGS. 6A and 6B). The portions (e.g., non-welding portions), which are not welded among the first protruding portions PRP1 and the second protruding portions PRP2, may correspond to the non-coupling portions NCP (e.g., refer to FIGS. 6A and 6B). The number of the welding portions among the first protruding portions PRP1 and the second protruding portions PRP2 is not limited to any one embodiment. Detailed description of the above-elements is provided below with reference to FIGS. 6A and 6B.

A welding apparatus WA may be provided on the welding portions among the first protruding portions PRP1 and the second protruding portions PRP2 and irradiate a beam to the portions of the first and second protruding portions PRP1 and PRP2. The portions of the first and second protruding portions PRP1 and PRP2 onto which the beam is irradiated may be melted to form the first welding portions WP1 (e.g., refer to FIGS. 6A and 6B). Accordingly, the first preliminary mask P-MK2 and the frame FR may be coupled to (or be integral with) each other. The portions among the first and second protruding portions PRP1 and PRP2 in which the first welding portions WP1 are formed may correspond to the coupling portions CP (e.g., refer to FIGS. 6A and 6B) to be described below. The first welding portions WP1 (e.g., refer to FIGS. 6A and 6B) may contain a material or an oxide thereof constituting the first and second protruding portions PRP1 and PRP2. The beam irradiated from the welding apparatus WA may be a heat ray or a laser beam. Hereafter, the above description may be equally applied to the welding apparatus WA. Detailed description of the welding apparatus WA is provided below in a subsequent process.

In the embodiment, it is illustrated as an example that the first preliminary mask P-M1 of FIG. 4A, in which the cutting portions CT are formed inside the non-deposition portion NEP is provided to the frame FR. However, the disclosure is not limited thereto. The cutting portions CT may be extended to the outer edge of the first preliminary mask P-MK2, and the first preliminary mask P-MK2 of FIG. 5 may be provided directly on the frame FR. Thus, the removing of at least a portion of the non-deposition portion NEP (e.g., refer to FIG. 4A) by cutting in the first trimming line TL1 (e.g., refer to FIG. 4A) may be omitted.

Each of FIGS. 6A and 6B corresponds to removing the non-coupling portion NCP from first preliminary masks P-MK3 and P-MK3a welded to the frame FR (S13) (e.g., refer to FIG. 3B). The coupling portions CP of the protruding portions PRP may be welded, and each of the first preliminary masks P-MK3 and P-MK3a of FIGS. 6A and 6B may be coupled to the frame FR. The preliminary mask assemblies P-MA illustrated in each of FIGS. 6A and 6B have substantially a same configuration. However, the number of the coupling portions CP and the non-coupling portions NCP may be changed.

Referring to FIGS. 6A and 6B, some of the protruding portions PRP may be welded by the welding apparatus WA (e.g., refer to FIG. 5) to form the first welding portions WP1. At least a portion of the coupling portions CP may be melted by the beam irradiated from the welding apparatus WA (e.g., refer to FIG. 5) and coupled to the upper surface of the frame FR, and each of the first welding portions WP1 may be formed. Each of the first welding portions WP1 may contain a metal oxide. The first welding portions WP1 may be formed, and the first preliminary mask P-MK3 may be fixed on the frame FR.

At least one first welding portion WP1 may be formed in a coupling portion CP among the protruding portions PRP. FIGS. 6A and 6B schematically illustrate as an example an embodiment in which first welding portions WP1 are formed in a coupling portion CP. When the first welding portions WP1 are formed in the coupling portion CP, the first preliminary mask P-MK3 or P-MK3a may be better (or more securely) fixed on the frame FR.

The number of the coupling portions CP and the non-coupling portions NCP among the protruding portions PRP may be variously changed according to a design. Accordingly, the number of the non-coupling portions NCP positioned between adjacent coupling portions CP in the first direction DR1 or the second direction DR2 may be changed.

In case that the number of the coupling portions CP among the protruding portions PRP is large, the first preliminary mask P-MK3 and the frame FR may be well (or securely) fixed to each other. As the number of the non-coupling portions NCP among the protruding portions PRP increases, compared to the number of the coupling portions CP, the number of times the frame FR is reused in case that the mask is replaced afterward may increase. Thus, in case that the number of the coupling portions CP among all the protruding portions PRP decreases, the degree of division (or the formation of division) into the coupling portions CP among the protruding portions PRP may increase. Accordingly, as the degree of division and formation into the coupling portions CP among the protruding portions PRP increases, the number of times the frame FR can be reused in case that the mask is replaced may increase.

Referring to FIG. 6A, the coupling portions CP and the non-coupling portions NCP may be alternately arranged in the first direction DR1 and the second direction DR2. For example, the number of non-coupling portions NCP positioned between adjacent coupling portions CP in the first direction DR1 or the second direction DR2 may be one.

According to an embodiment of the disclosure illustrated in FIG. 6A, the degree of division and formation into the coupling portions CP among the protruding portions PRP may correspond to two, and the number of times the frame FR can be reused without polishing the frame FR in case that the mask is replaced may be 2 times. If polishing the frame FR is further included in case that the mask is replaced, the number of times the frame FR is reused may be doubled. Detailed description of the above-described elements is provided below with reference to the drawings.

The embodiment of the disclosure is not limited thereto, and as illustrated in FIG. 6B, the degree of division and formation into the coupling portions CP among the protruding portions PRP may be increased. Referring to FIG. 6B, the number of non-coupling portions NCP positioned between adjacent coupling portions CP in the first direction DR1 and/or the second direction DR2 may be two. According to the embodiment of the disclosure illustrated in FIG. 6B, the degree of division and formation into the coupling portions CP among the protruding portions PRP may correspond to three. The number of times the frame FR can be reused without polishing the frame FR in case that the mask is replaced may be 3 times, and if polishing the frame FR is further included, the number of times the frame FR can be reused may be increased to six times.

The degree of division and formation into the coupling portions CP among the protruding portions PRP is not limited to the embodiments illustrated in FIGS. 6A and 6B.

Referring to FIGS. 6A and 6B, second trimming lines TL2 may be defined in the non-coupling portions NCP, respectively. The second trimming lines TL2 may be virtual lines corresponding to the boundaries between the non-coupling portions NCP and the deposition portion EP, respectively. According to an embodiment of the disclosure, the second trimming lines TL2 may be parallel to the second inner side surface IN2 of the first cutting portion CT1 (e.g., refer to FIG. 5) or the fourth inner side surface IN4 of the second cutting portion CT2 (e.g., refer to FIG. 5).

The cutting apparatus CA may be provided on the second trimming lines TL2 and irradiate a beam LS along the second trimming lines TL2. A portion corresponding to the second trimming lines TL2 may be cut from the first preliminary mask P-MK3 by the cutting apparatus CA, and the non-coupling portions NCP may be removed from the first preliminary mask P-MK3.

FIG. 7 is a schematic plan view of a mask assembly MA in which a first mask MK is formed on the frame FR through the aforementioned steps. The first mask MK of FIG. 7 may correspond to a state in which the non-coupling portions NCP (e.g., refer to FIG. 6A) have been removed from the first preliminary mask P-MK3 (e.g., refer to FIG. 6A).

Referring to FIG. 7, the first mask MK may include a deposition portion EP and coupling portions CP. In a plan view, the coupling portions CP may protrude from the deposition portion EP in a direction parallel to the first direction DR1 and/or the second direction DR2.

The coupling portions CP may be formed from the protruding portions PRP (e.g., refer to FIG. 5) of the first preliminary mask P-MK2 (e.g., refer to FIG. 5). For example, the coupling portions CP protruding from the deposition portion EP in a direction parallel to the second direction DR2 may be formed from the first protruding portions PRP1 (e.g., refer to FIG. 5). The coupling portions CP protruding from the deposition portion EP in a direction parallel to the first direction DR1 may be formed from the second protruding portions PRP2 (e.g., refer to FIG. 5).

As the non-coupling portion NCP (e.g., refer to FIG. 6A) is removed, the first mask MK may include first ends E-EP exposed to the outside and second ends corresponding to the ends E-PR of the coupling portions CP. Hereinafter, in this specification, the second ends are explained below by using the same reference numerals as the ends E-PR of the coupling portions CP.

The first ends E-EP may be positioned between the coupling portions CP in a plan view and connect the coupling portions CP to each other. Each of the first ends E-EP may correspond to an outer side surface of the deposition portion EP corresponding to a space (or region) between the coupling portions CP. The outer side surfaces of the deposition portion EP may be the ends of the deposition portion EP exposed from the coupling portions CP. The first ends E-EP and the second ends E-PR may be connected to each other and define an outer edge of the first mask MK.

Each of the first ends E-EP and the second ends E-PR may be parallel to the first direction DR1 or the second direction DR2. In a plan view, the second ends E-PR may protrude more toward an outer edge of the frame FR than the first ends E-EP. For example, the second ends E-PR parallel to the first direction DR1 may protrude more toward the outer edge of the frame FR in the second direction DR2 than the first ends E-EP parallel to the first direction DR1. The second ends E-PR parallel to the second direction DR2 may protrude more toward the outer edge of the frame FR in the first direction DR1 than the first ends E-EP parallel to the second direction DR2.

The first welding portions WP1 may overlap the coupling portions CP, respectively. The first welding portions WP1 may be formed in the coupling portions CP. The first mask MK and the frame FR may be coupled to each other by the first welding portions WP1.

The mask assembly MA may be disposed in the chamber CB of FIG. 1 and used in a deposition process. In case that the quality of the first mask MK is deteriorated because the mask assembly MA is used in the deposition process multiple times, or in case that the mass production of the to-be-processed object by using the first mask MK is finished, the replacement of the first mask MK may be needed.

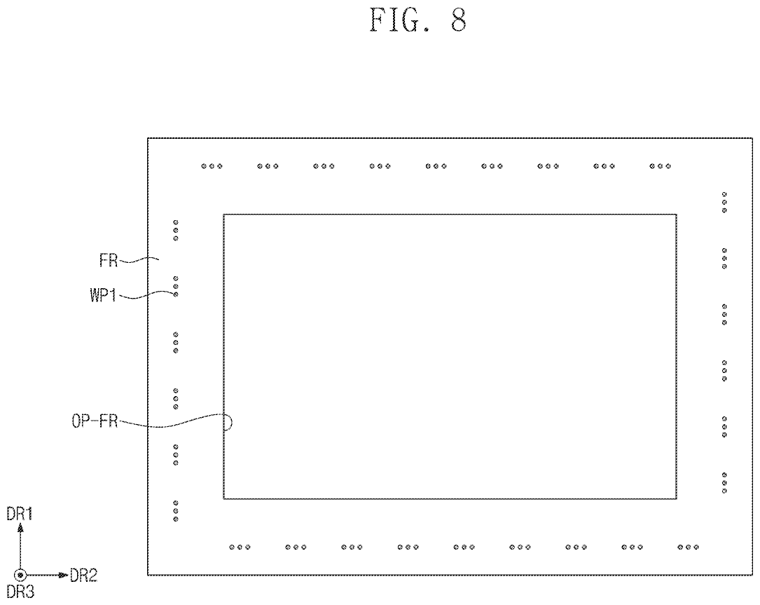

FIG. 8 corresponds to removing the first mask MK (e.g., refer to FIG. 7) from the frame FR to replace the first mask MK (e.g., refer to FIG. 7) (S20) (e.g., refer to FIG. 3B). Referring to FIG. 8, the first welding portions WP1 may remain on the frame FR from which the first mask MK (e.g., refer to FIG. 7) is removed. Some of the first welding portions WP1 may be spaced apart from each other by a distance corresponding to the width of the non-coupling portion NCP (e.g., refer to FIG. 6A).

In case that all of the protruding portions of the first preliminary mask are welded in the step illustrated in FIG. 5, the first welding portions remaining on the frame may be spaced apart from each other by less than about 2 mm. Thus, a region in which additional welding portions are formed may be insufficient. For example, it may be difficult to reuse the frame without polishing and removing the first welding portions on the frame.

According to an embodiment of the disclosure, however, some of the protruding portions PRP (e.g., refer to FIG. 5) of the first preliminary mask P-MK2 (e.g., refer to FIG. 5) may be welded, and the frame FR may have a sufficient region to form additional welding portions between the first welding portions WP1 remaining on the frame FR. Therefore, another mask may be formed on the frame FR without removing the first welding portions WP1 by polishing the frame FR. For example, in case that the mask is replaced, the frame FR may be reused without polishing the frame FR. Hereafter, detailed description of the forming of a second mask MKn (e.g., refer to FIG. 11A) on the frame FR of FIG. 8 is provided below with reference to the drawings.

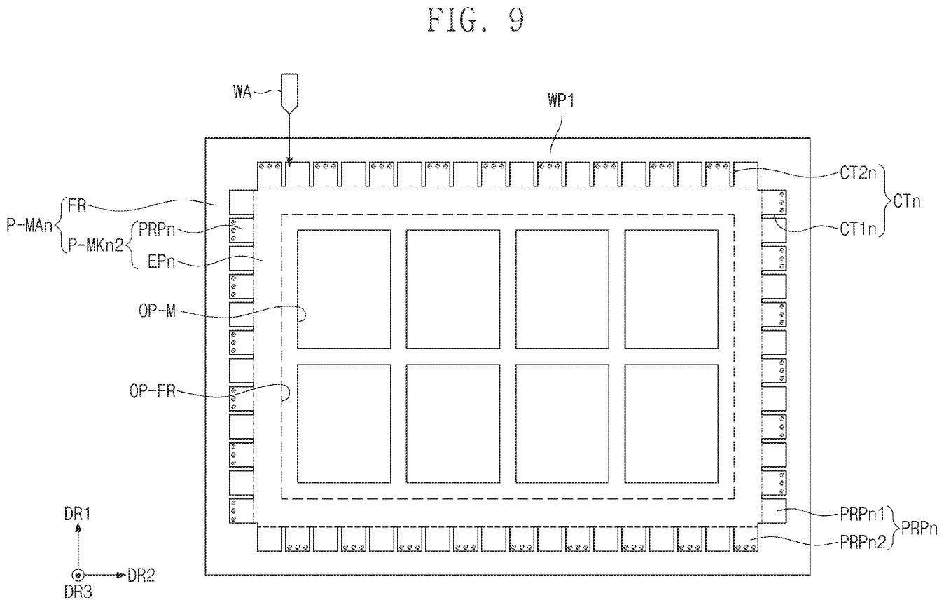

FIG. 9 corresponds to providing and welding a second preliminary mask P-MKn2 on the frame FR (S32) (e.g., refer to FIG. 3B). The frame FR and the second preliminary mask P-MKn2 provided on the frame FR may be referred to as a preliminary mask assembly P-MAn.

Cutting portions CTn may be formed from the second initial preliminary mask, and the second preliminary mask P-MKn2 may be provided. According to an embodiment of the disclosure, after a preliminary mask having the same area and shape as the aforementioned first preliminary mask P-MK1 of FIG. 4A is provided on the frame FR, the outer region of the first trimming line TL1 (e.g., refer to FIG. 4A) may be removed to form the second preliminary mask P-MKn2 of FIG. 9. However, the embodiment is not limited thereto, and the second preliminary mask P-MKn2 may be separately manufactured and provided on the frame FR.

Referring to FIG. 9, the second preliminary mask P-MKn2 may have substantially the same configuration as the first preliminary mask P-MK2 of FIG. 5. The second preliminary mask P-MKn2 may include a deposition portion EPn, protruding portions PRPn, and cutting portions CTn.

The deposition portion EPn of the second preliminary mask P-MKn2 and the deposition portion EP (e.g., refer to FIG. 5) of the first preliminary mask P-MK2 (e.g., refer to FIG. 5) may have a same area. The deposition openings OP-M formed in the deposition portion EPn of the second preliminary mask P-MKn2 and the deposition openings OP-M of the first preliminary mask P-MK2 (e.g., refer to FIG. 5) may have same area, shape, and arrangement. However, the embodiment of the disclosure is not limited thereto, and the deposition openings OP-M formed in the deposition portion EPn of the second preliminary mask P-MKn2 may be different from the deposition openings OP-M (e.g., refer to FIG. 5) of the first preliminary mask P-MK2 (e.g., refer to FIG. 5) in at least one of area, shape, and arrangement.

The protruding portions PRPn may include first protruding portions PRPn1 and second protruding portions PRPn2. The first protruding portions PRPn1 may protrude from the deposition portion EPn in a direction parallel to the second direction DR2, and the second protruding portions PRPn2 may protrude from the deposition portion EPn in a direction parallel to the first direction DR1. With respect to the first and second protruding portions PRPn1 and PRPn2, the descriptions of the first and second protruding portions PRP1 and PRP2 (e.g., refer to FIG. 5) of the first preliminary mask P-MK2 (e.g., refer to FIG. 5) may be equally applied. In addition, with respect to first cutting portions CTn1 formed between the first protruding portions PRPn1, and second cutting portions CTn2 formed between the second protruding portions PRPn2, the descriptions of the first and second cutting portions CT1 and CT2 (e.g., refer to FIG. 5) of the first preliminary mask P-MK2 (e.g., refer to FIG. 5) may be equally applied. Thus, detailed description of the same constituent elements is omitted.

However, the protruding portions PRPn of the second preliminary mask P-MKn2 may be different from the first and second protruding portions PRP1 and PRP2 of the first preliminary mask P-MK2 (e.g., refer to FIG. 5) at least in that some of the protruding portions PRPn of the second preliminary mask P-MKn2 may overlap the first welding portions WP1 remaining on the frame FR.

In the welding of the second preliminary mask P-MKn2, the protruding portions PRPn non-overlapping the first welding portions WP1 among the first and second protruding portions PRPn1 and PRPn2 may be welded to the frame FR. The welding apparatus WA may be provided on the protruding portions PRPn non-overlapping the first welding portions WP1 among the first and second protruding portions PRPn1 and PRPn2 and irradiate a beam thereon.

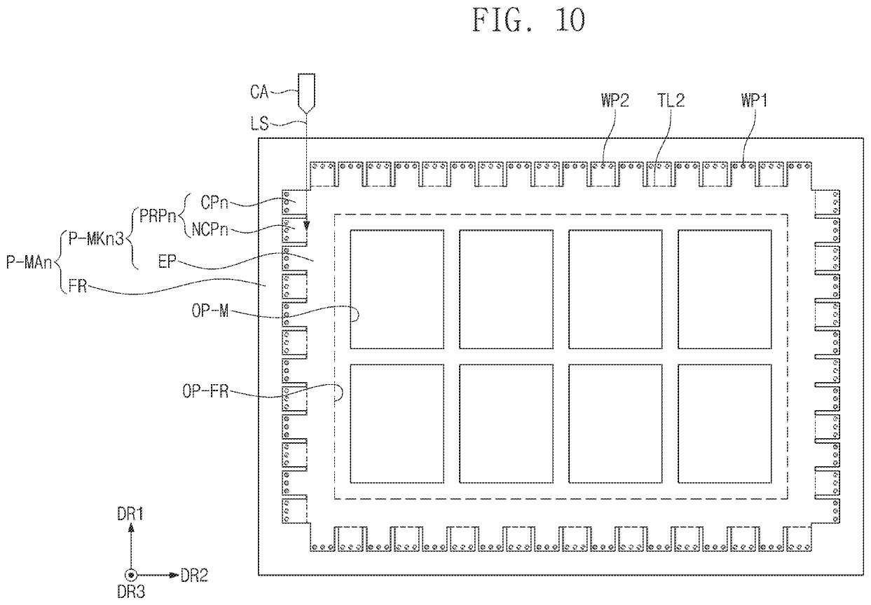

The welding portions non-overlapping the first welding portions WP1 among the first and second protruding portions PRPn1 and PRPn2 may correspond to the coupling portions CPn (e.g., refer to FIG. 10), and the non-welding portions non-overlapping the first welding portions WP1 or the portions overlapping the first welding portions WP1 among the first and second protruding portions PRPn1 and PRPn2 may correspond to the non-coupling portions NCPn (e.g., refer to FIG. 10).

FIG. 10 corresponds to removing the non-coupling portion NCPn from the second preliminary mask P-MKn3 welded to the frame FR (S33) (e.g., refer to FIG. 3B). The second preliminary mask P-MKn3 of FIG. 10 may correspond to the coupling portion CPn welded and coupled to the frame FR. FIG. 10 schematically illustrates an embodiment in which all portions non-overlapping the first welding portions WP1 among the first and second protruding portions PRPn1 and PRPn2 are welded.

Referring to FIG. 10, at least a portion of the coupling portion CPn non-overlapping the first welding portions WP1 among the protruding portions PRPn may be melted by the welding apparatus WA (e.g., refer to FIG. 9) and coupled to the upper surface of the frame FR. Thus, second welding portions WP2 may be formed. Each of the second welding portions WP2 may contain a metal oxide. The second welding portions WP2 may be formed, and the second preliminary mask P-MKn3 may be fixed on the frame FR.

The non-coupling portions NCPn may respectively overlap the first welding portions WP1 in a plan view. However, the disclosure is not limited thereto, and some of the protruding portions PRPn non-overlapping the first welding portions WP1 may not be welded in the welding step, and some of the non-coupling portions NCPn may non-overlap the first welding portions WP1.

The second trimming lines TL2 corresponding to the boundaries between the non-coupling portions NCPn and the deposition portion EPn may be respectively defined in the non-coupling portions NCPn. The cutting apparatus CA may be provided on the second trimming lines TL2 and irradiate a beam LS along the second trimming lines TL2. A portion (e.g., a portion of the second preliminary mask P-MKn3) corresponding to the second trimming lines TL2 may be cut from the second preliminary mask P-MKn3 by the cutting apparatus CA, and the non-coupling portions NCPn may be removed from the second preliminary mask P-MKn3.

FIG. 11A is a schematic plan view of a mask assembly MAn in which the second mask MKn is formed on the frame FR through the aforementioned steps. FIG. 11B is a schematic cross-sectional view of the mask assembly MAn corresponding to line I-I′ in FIG. 11A. The second mask MKn of FIGS. 11A and 11B may correspond to a state in which the non-coupling portions NCPn (e.g., refer to FIG. 10) have been removed from the second preliminary mask P-MK3n (e.g., refer to FIG. 10). For example, the second mask MKn of FIGS. 11A and 11B may correspond to a second preliminary mask P-MK3n (e.g., refer to FIG. 10) without the non-coupling portions NCPn (e.g., refer to FIG. 10).

Referring to FIGS. 11A and 11B, the second mask MKn may include a deposition portion EPn and coupling portions CPn. The coupling portions CPn may protrude from the deposition portion EPn in a direction parallel to the first direction DR1 and/or the second direction DR2. The coupling portions CPn (e.g., some of the coupling portions CPn) protruding from the deposition portion EPn in a direction parallel to the second direction DR2 may be formed from the first protruding portions PRPn1 (e.g., refer to FIG. 9). The coupling portions CPn (e.g., remaining of the coupling portions CPn) protruding from the deposition portion EPn in a direction parallel to the first direction DR1 may be formed from the second protruding portions PRPn2 (e.g., refer to FIG. 9).

The second mask MKn may include first ends E-EP and second ends E-PR. Each of the first ends E-EP and the second ends E-PR may be parallel to the first direction DR1 or the second direction DR2. The first ends E-EP and the second ends E-PR may be connected to each other and define an outer edge of the second mask MKn.

The non-coupling portions NCPn (e.g., refer to FIG. 10) may be removed, and the first ends E-EP may correspond to portions exposed to the outside. For example, the first ends E-EP may respectively correspond to outer side surfaces of the deposition portion EPn corresponding to regions spaced apart from each other between the coupling portions CPn. The outer side surfaces of the deposition portion EPn may be ends of the deposition portion EPn exposed from the coupling portions CPn. The first ends E-EP may be positioned between the coupling portions CPn in a plan view and connect the coupling portions CPn to each other.

The second ends E-PR may respectively correspond to the ends E-PR of the coupling portions CPn. The second ends E-PR may protrude more toward the outer edge of the frame FR than the first ends E-EP in a plan view. For example, the second ends E-PR parallel to the first direction DR1 may protrude more toward the outer edge of the frame FR in the second direction DR2 than the first ends E-EP parallel to the first direction DR1. The second ends E-PR parallel to the second direction DR2 may protrude more toward the outer edge of the frame FR in the first direction DR1 than the first ends E-EP parallel to the second direction DR2.

The first welding portions WP1 and the second welding portions WP2 may be arranged in the first direction DR1 and the second direction DR2. For example, in case that the first welding portions WP1 disposed between two coupling portions CPn adjacent to each other are defined as a first welding portion group, and the second welding portions WP2 overlapping a coupling portion CPn are defined as a second welding portion group, the first welding portion group and the second welding portion group may be provided in plurality and alternately disposed in the first direction DR1 and the second direction DR2.

Each of the second welding portions WP2 may protrude from the upper surface FR-U of the frame FR and be formed in the coupling portions CPn. For example, the second welding portions WP2 may be respectively formed inside the second ends E-PR corresponding to the ends E-PR of the coupling portions CPn. Accordingly, the second welding portions WP2 may couple the second mask MKn and the frame FR to each other.

As the non-coupling portion NCPn (e.g., refer to FIG. 10) is removed, the first welding portions WP1 overlapping the non-coupling portion NCPn (e.g., refer to FIG. 10) may be exposed to the outside. The first welding portions WP1 remaining on the frame FR may protrude from the upper surface FR-U of the frame FR.

The first ends E-EP may face the first welding portions WP1 and be spaced apart from each other. The first ends E-EP parallel to the first direction DR1 may face the first welding portions WP1 in the second direction DR2, and the first ends E-EP parallel to the second direction DR2 may face the first welding portions WP1 in the first direction DR1.

The second mask MKn according to an embodiment of the disclosure may be spaced apart from the first welding portions WP1 and coupled onto the frame FR on which the first welding portions WP1 remain. For example, without an additional process in which the first welding portions WP1 are removed, the first mask MK (refer to FIG. 7) may be replaced with the second mask MKn by reusing the frame FR to which the first mask MK (e.g., refer to FIG. 7) is coupled. Thus, it is possible to increase the number of times the frame FR is reused in case that the mask is replaced, and it is also possible to reduce the cost required for manufacturing a new frame FR.

FIG. 12 is a schematic plan view of a mask assembly according to an embodiment of the disclosure. The mask assembly MAn-1 of FIG. 12 includes substantially identical or similar configuration as the mask assembly MKn of the embodiment illustrated in FIG. 11 and further includes additional configuration elements (e.g., mask parts UMK) in addition to the configuration elements of the mask assembly MKn. Hereinafter, the detailed description of the same configuration will be omitted and the description will be focused on the additional configuration elements.

Referring to FIG. 12, the mask assembly MAn-1 may further include mask parts UMK. The mask parts UMK may be disposed on the second mask MKn and coupled to the second mask MKn.

The mask parts UMK may be respectively disposed to correspond to the deposition openings OP-M. For example, the mask parts UMK may respectively overlap the deposition openings OP-M in a plan view. An arrangement of the mask parts UMK may be arranged to correspond to the arrangement of the deposition openings OP-M. FIG. 12 exemplarily illustrates as an example eight mask parts UMK arranged in the first direction DR1 and the second direction DR2. However, the arrangement and number of the mask parts UMK are not limited thereto and may be variously changed. For example, the mask parts UMK may be provided as stick masks extending in a direction and may be arranged in a direction crossing (or intersecting) the extending direction of the mask parts UMK.

Each of the mask parts UMK may include cell openings OP-U. Each of the cell openings OP-U may pass through a corresponding mask part UMK. In a plan view, the cell openings OP-U may respectively overlap the deposition openings OP-M and the frame opening OP-FR.

Each of the cell openings OP-U may have a quadrangular shape in a plan view. However, the disclosure is not limited thereto, and the shape of the cell openings OP-U may be variously changed into a polygonal shape, a circular shape, an oval shape, or the like.

The cell openings OP-U may overlap corresponding deposition openings OP-M among the deposition openings OP-M. The cell openings OP-U may have an arrangement (e.g., a predetermined or selectable arrangement), and define a region in which the deposition material EM (e.g., refer to FIG. 1) is deposited on the substrate SUB (e.g., refer to FIG. 1). For example, the deposition material EM (e.g., refer to FIG. 1) injected from the deposition part EU (e.g., refer to FIG. 1) may pass through the frame opening OP-FR, the deposition openings OP-M, and the cell openings OP-U and form a deposition pattern, which corresponds to the shape and arrangement of the cell openings OP-U, on the substrate SUB (e.g., refer to FIG. 1). In an embodiment of the disclosure, the deposition pattern may correspond to the light-emitting layer EML (e.g., refer to FIG. 2) of the display panel DP (e.g., refer to FIG. 2). However, the embodiment of the deposition pattern is not limited thereto.

The mask parts UMK may contain a metal material. For example, the mask parts UMK may contain at least one of stainless steel (SUS), an invar alloy, nickel (Ni), and cobalt (Co). However, the disclosure is not limited thereto.

Although an embodiment in which the mask parts UMK are disposed on the second mask MKn is schematically illustrated as an example, the embodiment of the disclosure is not limited thereto, and the mask parts UMK may be additionally disposed on the first mask MK of FIG. 7.

The mask assembly MAn including the second mask MKn may be disposed in the chamber CB (e.g., refer to FIG. 1) and used in a deposition process. In case that the quality of the second mask MKn is deteriorated or the mass production of a to-be-processed object by using the second mask MKn is finished, the replacement of the second mask MKn may be needed.

In case that a sufficient region for forming additional welding portions may be secured between the first and second welding portions WP1 and WP2 remaining on the frame FR, a new third preliminary mask may be provided on the frame FR, and a mask assembly in which the mask is replaced may be manufactured by forming additional welding portions. As described above, the number of times the frame is reused in case that the mask is replaced may vary depending on the degree of division and formation into the coupling portions among the protruding portions of the preliminary mask.

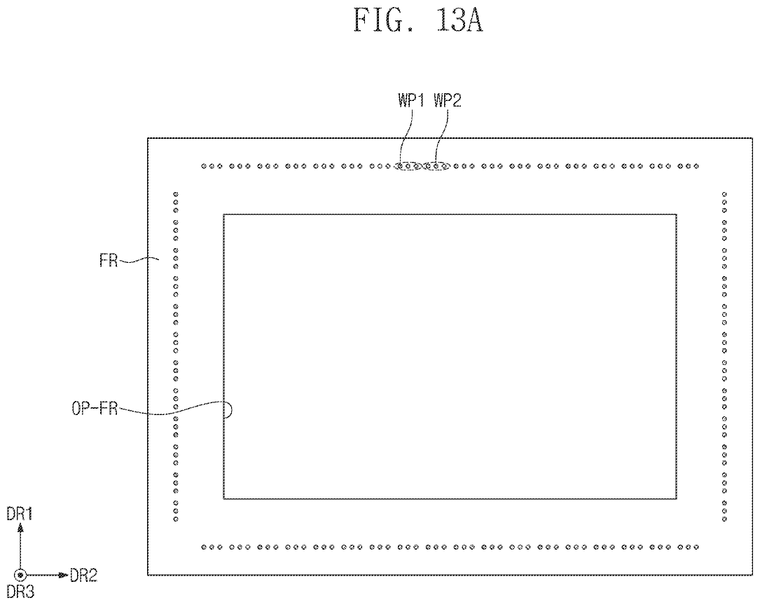

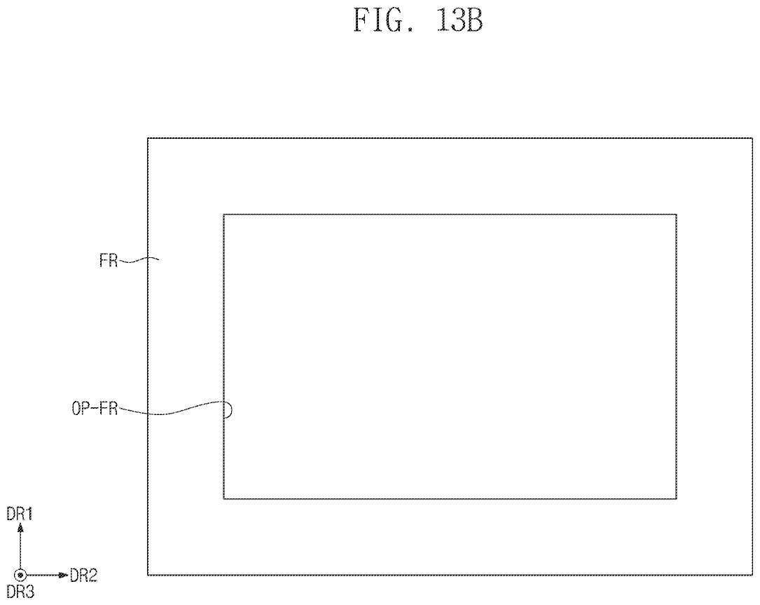

However, in case that a region for forming additional welding portions is insufficient due to the first and second welding portions WP1 and WP2 remaining on the frame FR, the mask replacement method according to an embodiment of the disclosure may further include polishing the frame FR in order to further increase the number of times the frame FR is reused. Detailed description of the above-described elements is provided below with reference to FIGS. 13A and 13B.

FIGS. 13A and 13B are schematic plan views corresponding to a step of the mask replacement method according to an embodiment of the disclosure. FIG. 13A is a plan view of the frame FR after the second mask MKn (e.g., refer to FIG. 11) has been removed from the frame FR to replace the second mask MKn (e.g., refer to FIG. 11). FIG. 13B is a plan view of the frame FR after polishing.

Referring to FIG. 13A, the first and second welding portions WP1 and WP2 may remain on the frame FR from which the second mask MKn (e.g., refer to FIG. 11) is removed. The first and second welding portions WP1 and WP2 may be arranged in the first direction DR1 and the second direction DR2, and a region between the first and second welding portions WP1 and WP2 may be insufficient for forming additional welding portions. Accordingly, the frame FR, on which the first and second welding portions WP1 and WP2 remain, may be polished for reuse. For example, the frame FR may be polished to remove the first and second welding portions WP1 and WP2.

Referring to FIG. 13B, the first and second welding portions WP1 and WP2 (e.g., refer to FIG. 13A) may be removed from the upper surface of the polished frame FR. Accordingly, a new mask may be coupled onto the polished frame FR. Since the mask replacement method according to an embodiment of the disclosure further includes polishing the frame FR, the number of times the frame FR is reused may be increased.

In case that the frame FR is polished multiple times, the frame FR may be damaged. Thus, the number of times the frame FR is polished may be limited. However, since the mask replacement method according to an embodiment of the disclosure provides a method for reusing the frame FR without polishing the frame FR, the number of times the frame FR is reused may be increased.

The frame FR of the mask assembly MA according to an embodiment of the disclosure may include recessed portions. Detailed description of a mask replacement method using the frame FR including the recessed portions is provided below with reference to the drawings.

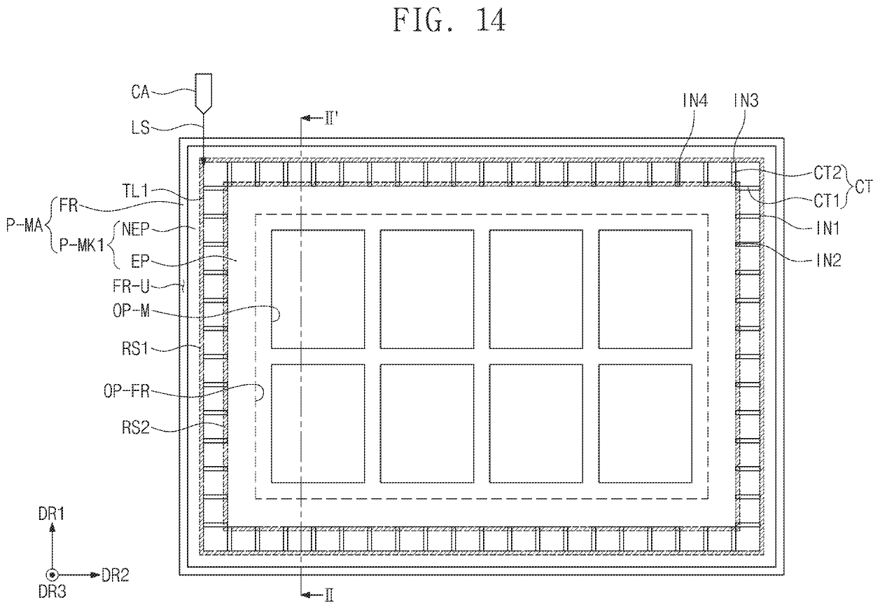

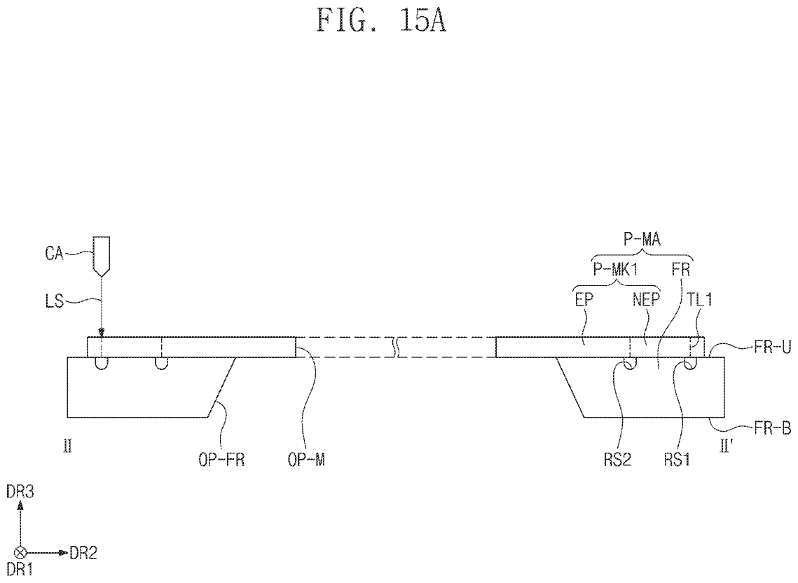

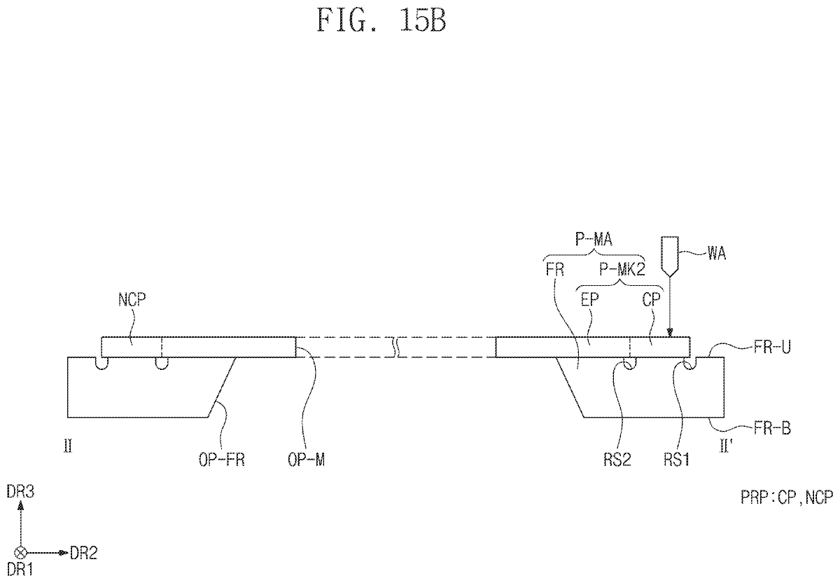

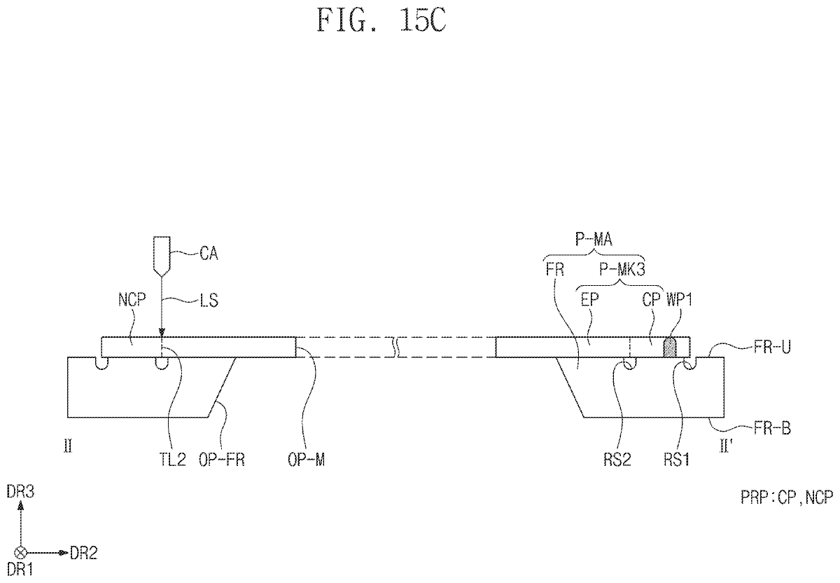

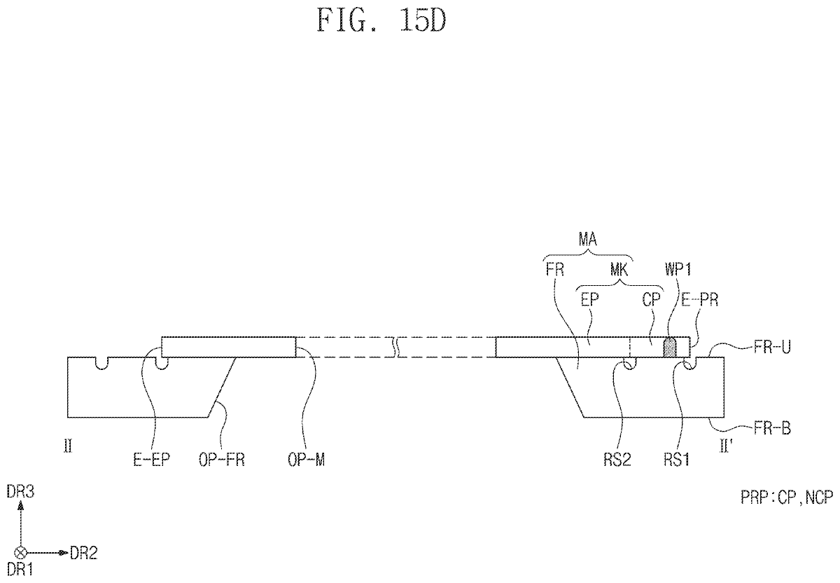

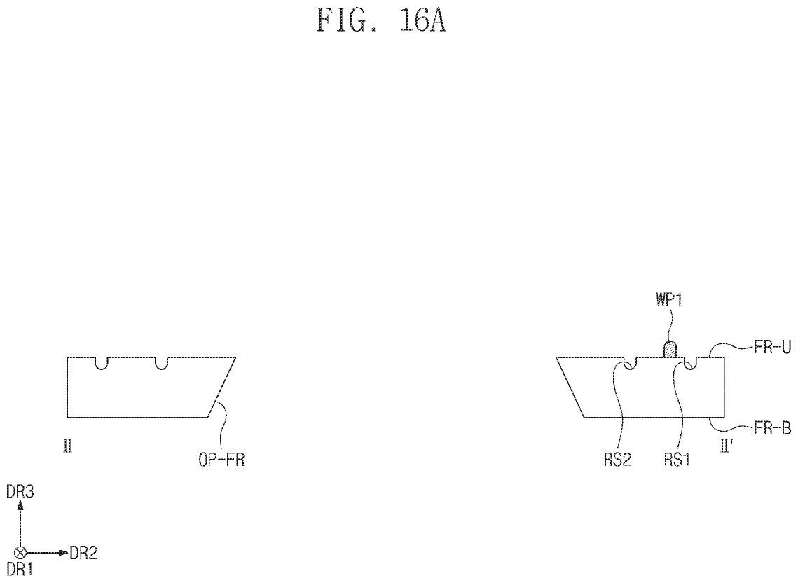

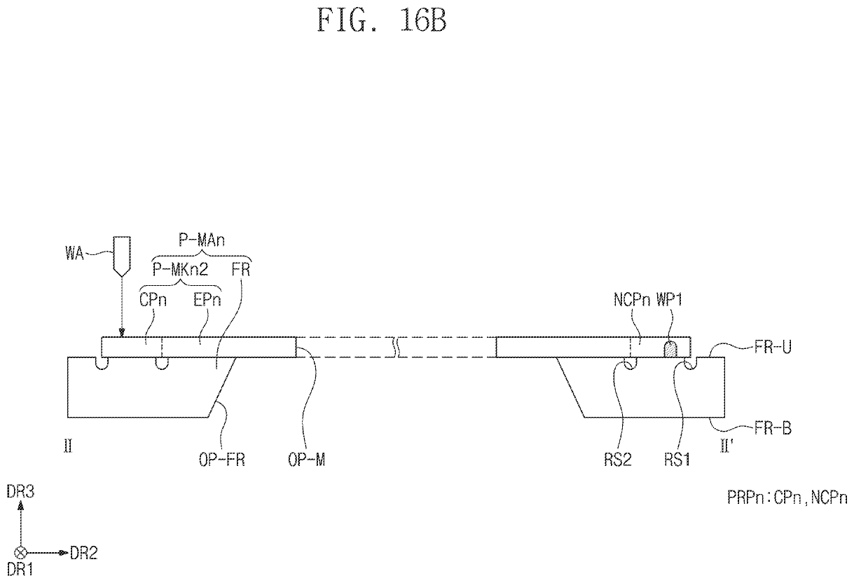

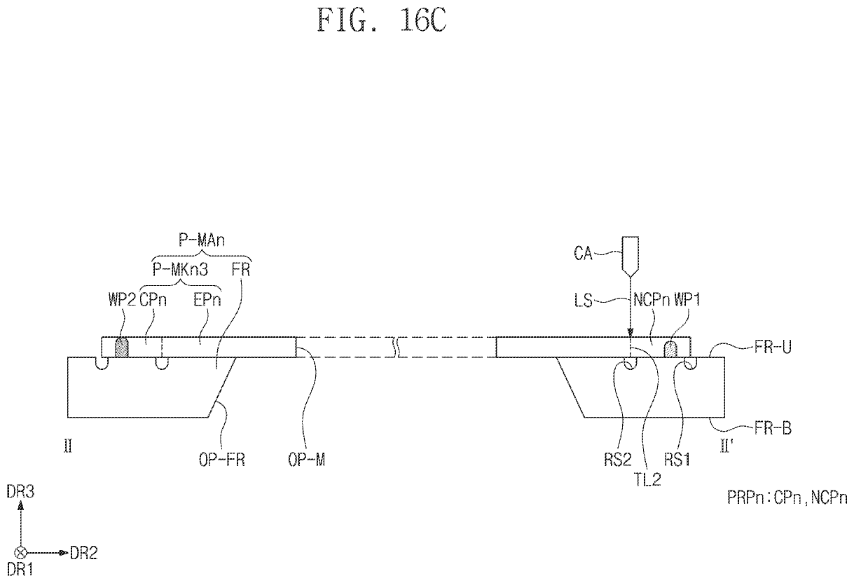

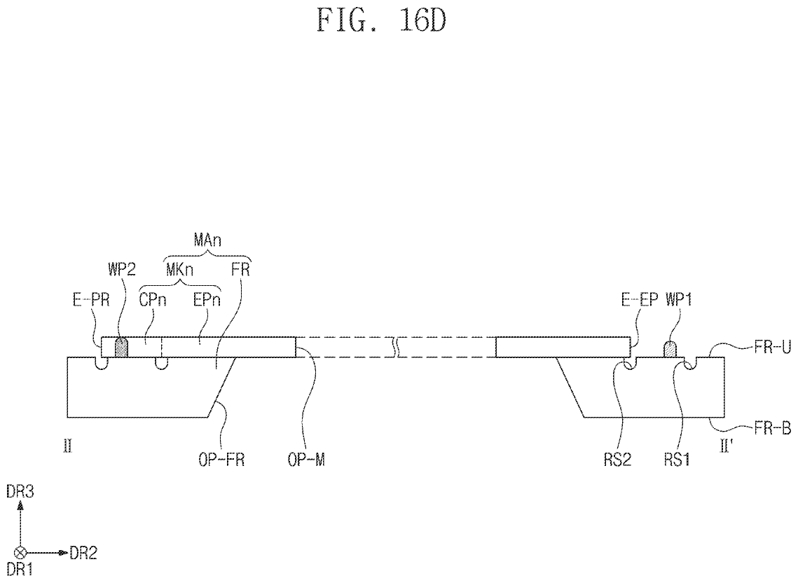

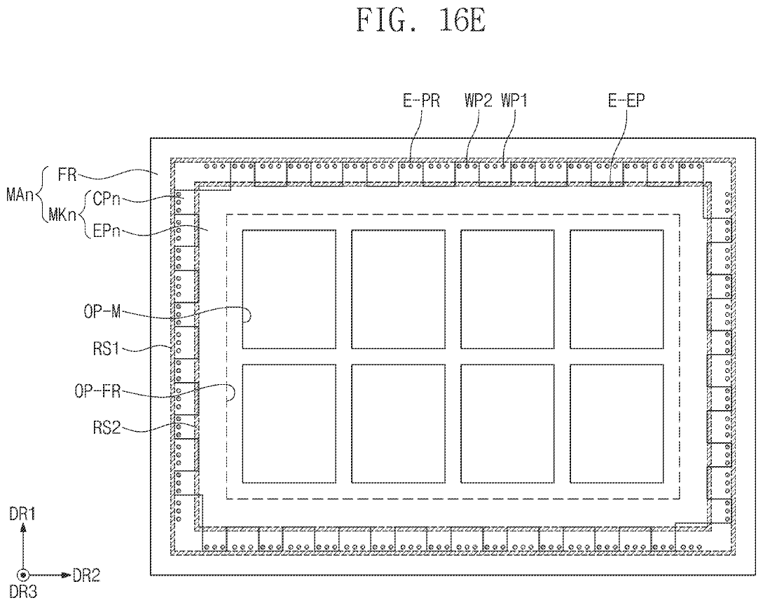

FIG. 14 is a schematic plan view corresponding to providing the first preliminary mask P-MK1 (S11) (e.g., refer to FIG. 3B). FIG. 15A is a schematic cross-sectional view of the preliminary mask assembly P-MA corresponding to line II-IT of FIG. 14. FIGS. 15B to 15D and 16A to 16D are schematic cross-sectional views illustrating steps in which the mask is replaced on a cross section corresponding to line II-IT of FIG. 14. FIG. 16E is a schematic plan view of the mask assembly according to an embodiment of the disclosure corresponding to the step in FIG. 16D.

The step illustrated in FIG. 14 may be substantially the same as the step illustrated in FIG. 4A and be different from the step illustrated in FIG. 4A at least in the configuration of the frame FR. Accordingly, with respect to the components illustrated in FIG. 14, the aforementioned description may be equally applied, and hereafter, the description is focused on the difference between the frames FR.

Referring to FIGS. 14 and 15A, the frame FR may include a first recessed portion RS1 and a second recessed portion RS2. The first recessed portion RS1 and the second recessed portion RS2 may be recessed toward the lower surface FR-B from the upper surface FR-U of the frame FR. The first recessed portion RS1 may be more adjacent to the outside of the frame FR than the second recessed portion RS2.

In a plan view, the first recessed portion RS1 may overlap the first inner side surfaces IN1 of the first cutting portions CT1 and the third inner side surfaces IN3 of the second cutting portions CT2. For example, the first recessed portion RS1 may overlap the first trimming line TL1 in a plan view. The first recessed portion RS1 may indicate a portion, in which the first trimming line TL1 is defined in the first preliminary mask P-MK1, and play (or function as) an auxiliary role so that the first preliminary mask P-MK1 can be cut exactly along the first trimming line TL1.

In a plan view, the second recessed portion RS2 may overlap the second inner side surfaces IN2 of the first cutting portions CT1 and the fourth inner side surfaces IN4 of the second cutting portions CT2. The second recessed portion RS2 may correspond to a boundary between the deposition portion EP and the non-deposition portion NEP and overlap a virtual line connecting the second inner side surfaces IN2 and the fourth inner side surfaces IN4 to each other. For example, the second recessed portion RS2 may overlap the second trimming lines TL2 (e.g., refer to FIG. 6A) of a subsequent process in a plan view.

A subsequent process may include cutting the first preliminary mask P-MK3 (e.g., refer to FIG. 6A) along the second trimming lines TL2 (e.g., refer to FIG. 6A) to remove the non-coupling portion NCP (e.g., refer to FIG. 6A). The second recessed portion RS2 may indicate a portion in which the second trimming lines TL2 (e.g., refer to FIG. 6A) are defined in the first preliminary mask P-MK3 (e.g., refer to FIG. 6A). The second recessed portion RS2 may play an auxiliary role so that the first preliminary mask P-MK3 (e.g., refer to FIG. 6A) can be cut exactly along the second trimming lines TL2 (e.g., refer to FIG. 6A).

Each of the first recessed portion RS1 and the second recessed portion RS2 may have a closed line shape surrounding the frame opening OP-FR in a plan view. However, the shapes of the first recessed portion RS1 and the second recessed portion RS2 are not limited to any one embodiment as long as they can play an auxiliary role so that the preliminary mask can be cut along the trimming lines.

The cutting apparatus CA may be disposed on the first recessed portion RS1. The cutting apparatus CA may irradiate the beam LS along the first trimming line TL1 overlapping the first recessed portion RS1. The first recessed portion RS1 may play an auxiliary role so that the cutting apparatus CA may be aligned at a correct position to irradiate the beam LS onto the correct position. Accordingly, the reliability of the process of cutting the first preliminary mask P-MK1 may be improved due to the first recessed portion RS1.

FIG. 15B corresponds to removing the outer region of the first trimming line TL1 (e.g., refer to FIG. 15A) of the non-deposition portion NEP (e.g., refer to FIG. 15A) and welding the first preliminary mask P-MK2 (S12) (e.g., refer to FIG. 3B). With respect to the step corresponding to FIG. 15B, the description given above with reference to FIG. 5 may be equally applied.

Referring to FIG. 15B, an end defining the outer edge of the first preliminary mask P-MK2 may overlap the first recessed portion RS1. By confirming that the end of the first preliminary mask P-MK2 overlaps the first recessed portion RS1, it is possible to check whether or not the process of cutting the first preliminary mask P-MK1 (FIG. 15A) has been performed as designed.

In order to couple the first preliminary mask P-MK2 and the frame FR to each other, the welding apparatus WA may be provided on the coupling portion CP of the first preliminary mask P-MK2 to weld the coupling portion CP to the frame FR. In a plan view, the welding apparatus WA may be aligned with a region between the first recessed portion RS1 and the second recessed portion RS2. For example, the welding apparatus WA may irradiate a beam onto a portion located more inward than the end of the coupling portion CP overlapping the first recessed portion RS1.

FIG. 15C corresponds to welding the coupling portion CP to the frame FR and removing the non-coupling portion NCP (S13) (e.g., refer to FIG. 3B). With respect to the step corresponding to FIG. 15C, the description given above with reference to FIG. 6A may be equally applied.

Referring to FIG. 15C, a first welding portion WP1 coupling the coupling portion CP to the frame FR may be formed in the coupling portion CP. In a plan view, the first welding portion WP1 may be formed in a region between the first recessed portion RS1 and the second recessed portion RS2.

The second trimming line TL2 corresponding to the boundary between the non-coupling portion NCP and the deposition portion EP may overlap the second recessed portion RS2 in a plan view. In order to remove the non-coupling portion NCP, the cutting apparatus CA may be aligned to be disposed on the second recessed portion RS2. Thereafter, the cutting apparatus CA may irradiate a beam LS along the second trimming line TL2 overlapping the second recessed portion RS2. The second recessed portion RS2 may play an auxiliary role so that the cutting apparatus CA can be aligned at a correct position and irradiate the beam LS onto the correct position. Thus, the reliability of the process of removing the non-coupling portion NCP may be improved.

FIG. 15D is a cross section of a mask assembly MA in which the non-coupling portion NCP (e.g., refer to FIG. 15C) is removed from the first preliminary mask P-MK3 (e.g., refer to FIG. 15C) and the first mask MK is formed on the frame FR. With respect to the mask assembly MA of FIG. 15D, the description given above with reference to FIG. 7 may be equally applied.

Referring to FIG. 15D, the non-coupling portion NCP (e.g., refer to FIG. 15C) may be removed, and at least a portion of the end of the deposition portion EP may be exposed to the outside. The portion of the end of the deposition portion EP may correspond to the first end E-EP of the first mask MK. The first end E-EP may overlap the second recessed portion RS2 in a plan view. The second end E-PR of the first mask MK corresponding to the end E-PR of the coupling portion CP may overlap the first recessed portion RS1 in a plan view.

FIG. 16A corresponds to removing the first mask MK (e.g., refer to FIG. 15D) from the frame FR (S20) (e.g., refer to FIG. 3B) to replace the first mask MK (e.g., refer to FIG. 15D). With respect to the step corresponding to FIG. 16A, the description given above with reference to FIG. 8 may be equally applied.

Referring to FIG. 16A, the first welding portion WP1 may remain on the frame FR from which the first mask MK (e.g., refer to FIG. 15D) is removed. The remaining first welding portion WP1 may protrude from the upper surface FR-U of the frame FR. In the mask replacement method according to an embodiment of the disclosure, a new mask may be formed on the frame FR without removing the remaining first welding portion WP1.

FIG. 16B corresponds to providing and welding the second preliminary mask P-MKn2 on the frame FR (S31) (e.g., refer to FIG. 3B) to form a new mask on the frame FR. With respect to the step corresponding to FIG. 16B, the description given above with reference to FIG. 9 may be equally applied.

Referring to FIG. 16B, an end defining the outer edge of the second preliminary mask P-MKn2 may overlap the first recessed portion RS1. Like the first preliminary mask P-MK2 (e.g., refer to FIG. 15B), the second preliminary mask P-MKn2 of FIG. 16B may be formed through the step illustrated in FIG. 15A. However, the embodiment of the disclosure is not limited thereto.

The non-coupling portion NCPn of the second preliminary mask P-MKn2 may overlap the first welding portion WP1. The non-coupling portion NCPn may not be readily coupled to the frame FR by the first welding portion WP1, and the non-coupling portion NCPn may be removed through a subsequent process.

The welding apparatus WA may be disposed on the coupling portion CPn and irradiate a beam onto a portion (e.g., a portion of the frame FR) located more inward than the end of the coupling portion CPn overlapping the first recessed portion RS1. The welding apparatus WA may be aligned in a region between the first recessed portion RS1 and the second recessed portion RS2 in a plan view. The welding apparatus WA may irradiate the beam onto the coupling portion CPn to weld the coupling portion CPn of the second preliminary mask P-MKn2 to the frame FR.

FIG. 16C corresponds to welding the coupling portion CPn of the second preliminary mask P-MKn3 to the frame FR and removing the non-coupling portion NCPn (S33) (e.g., refer to FIG. 3B). With respect to the step corresponding to FIG. 16C, the description given above with reference to FIG. 10 may be equally applied.

Referring to FIG. 16C, a second welding portion WP2 coupling the coupling portion CPn and the frame FR to each other may be formed in the coupling portion CPn. The second welding portion WP2 may be formed in a region between the first recessed portion RS1 and the second recessed portion RS2 in a plan view. The second welding portion WP2 may be spaced apart from the first welding portion WP1.

The second trimming line TL2 corresponding to the boundary between the non-coupling portion NCPn and the deposition portion EPn of the second preliminary mask P-MKn3 may overlap the second recessed portion RS2 in a plan view. The cutting apparatus CA may be aligned to be disposed on the second recessed portion RS2 and irradiate a beam LS along the second trimming line TL2, and the non-coupling portion NCPn may be removed. The second recessed portion RS2 may play the auxiliary role, and the cutting apparatus CA may be aligned at a correct position and irradiate the beam LS onto the correct position. Thus, the reliability of the process of removing the non-coupled portion NCPn may be improved.

FIG. 16D is a cross-sectional view of the mask assembly Man in which a second mask MKn is formed on the frame FR by removing the non-coupling portion NCPn (e.g., refer to FIG. 16C) from the second preliminary mask P-MKn3 (e.g., refer to FIG. 16C). FIG. 16E is a plan view of the mask assembly MAn of FIG. 16D. With respect to the mask assembly MAn of FIGS. 16D and 16E, the description given above with reference to FIGS. 11A and 11B may be equally applied.

Referring to FIGS. 16D and 16E, the non-coupling portion NCPn (e.g., refer to FIG. 15D) may be removed, and at least a portion of the end of the deposition portion EPn may be exposed to the outside. The exposed portion of the end of the deposition portion EPn may correspond to the first end E-EP of the second mask MKn. The first end E-EP may be spaced apart from the first welding portion WP1 and face the first welding portion WP1. The first end E-EP may overlap the second recessed portion RS2 in a plan view. The second end E-PR of the second mask MKn corresponding to the end E-PR of the coupling portion CPn may overlap the first recessed portion RS1 in a plan view.

In a plan view, the coupling portions CPn of the second mask MKn and the first and second welding portions WP1 and WP2 may be disposed on a region between the first recessed portion RS1 and the second recessed portion RS2. In a plan view, the deposition portion EPn of the second mask MKn may be disposed on an inner region of the second recessed portion RS2.

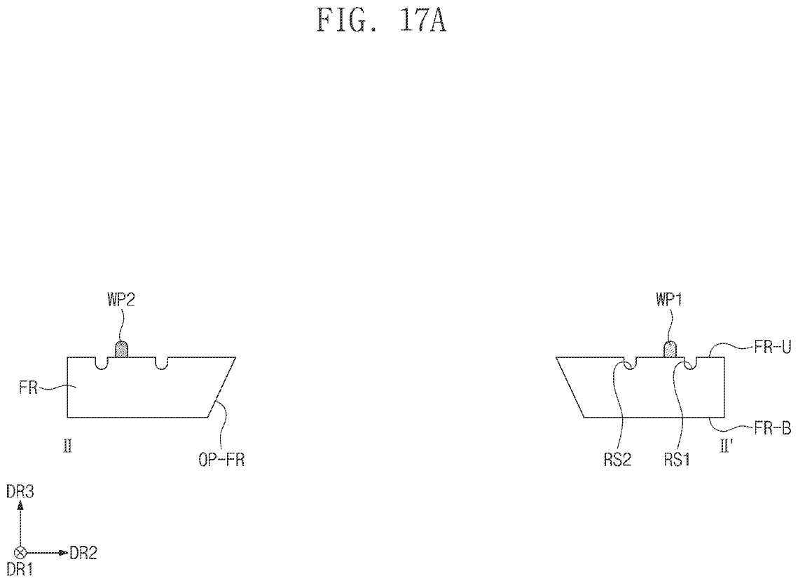

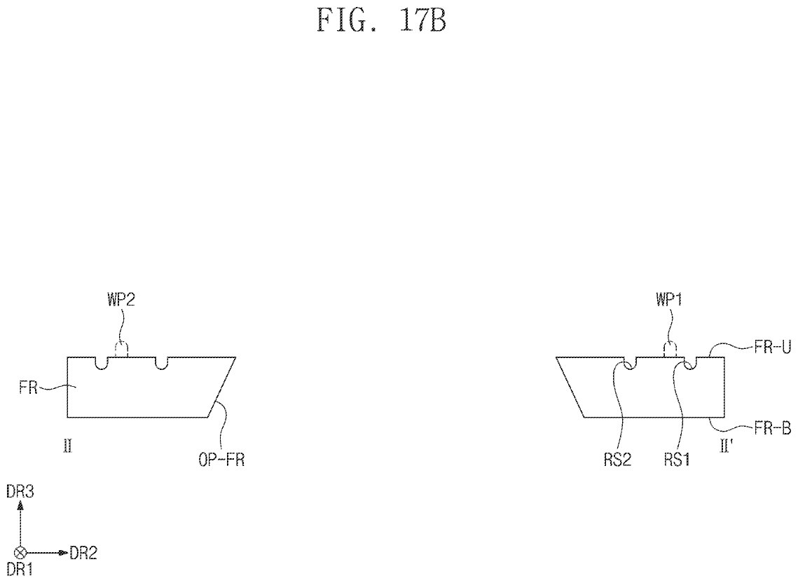

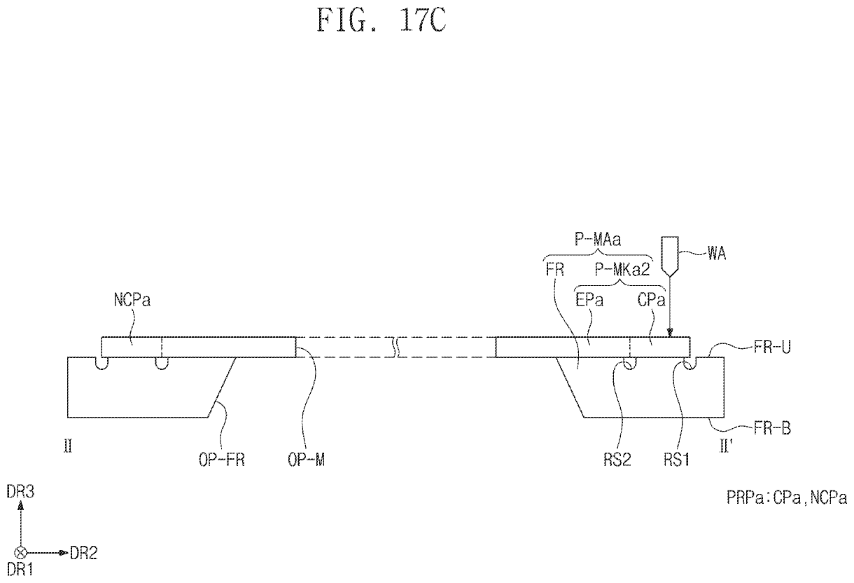

FIG. 17A corresponds to removing the second mask MKn (e.g., refer to FIG. 16C) from the frame FR to replace the second mask MKn (e.g., refer to FIG. 16C). FIG. 17B corresponds to polishing the frame FR to remove the first and second welding portions WP1 and WP2. With respect to the steps corresponding to FIGS. 17A and 17B, the description given above with reference to FIGS. 13A and 13B may be equally applied.

Referring to FIG. 17A, the first welding portion WP1 and the second welding portion WP2 may remain on the frame FR from which the second mask MKn (e.g., refer to FIG. 16C) is removed. The remaining first and second welding portions WP1 and WP2 may protrude from the upper surface FR-U of the frame FR.

Referring to FIG. 17B, the frame FR may be polished, and a new mask may be coupled on the frame FR. The first and second welding portions WP1 and WP2 may be removed from the upper surface FR-U of the polished frame FR. For the convenience of understanding, FIG. 17B illustrates the removed first and second welding portions WP1 and WP2 with dotted lines. Through the polishing of the frame FR, the frame FR may have a sufficient region in which new welding portions are formed and to which the new mask is coupled. For example, the polishing of the frame FR may be added, and the number of times the frame FR is reused in case that the mask is replaced may be increased.

FIG. 17C corresponds to providing the third preliminary mask P-MKa2 on the frame FR to form a new mask on the frame FR. The frame FR and the third preliminary mask P-MKa2 provided on the frame FR may be referred to as a preliminary mask assembly P-MAa.

The third preliminary mask P-MKa2 and the first preliminary mask P-MK2 (or the second preliminary mask P-MKn2) may have same area and shape. Description of the first preliminary mask P-MK2 and the second preliminary mask P-MKn2 is provided above. Referring to FIG. 17C, an end defining the outer edge of the third preliminary mask P-MKa2 may overlap the first recessed portion RS1. The boundary between the non-coupling portion NPCa and the deposition portion EPa may overlap the second recessed portion RS2.

The welding apparatus WA may be provided on the coupling portion CPa to weld the coupling portion CPa to the frame FR, and the third preliminary mask P-MKa2 and the frame FR may be coupled to each other. A third mask coupled to the frame FR may be formed from the third preliminary mask P-MKa2. The third mask and the first mask MK1 may be formed through same steps. Description of the first mask MK1 is provided above.

The welding portions in the coupling portions of the mask according to an embodiment of the disclosure may be formed by welding some of the protruding portions of the preliminary mask. Thus, the welding portions may be spaced apart from each other on the frame by a distance (e.g., a predetermined or selectable distance) with a sufficient region to form additional welding portions. Hereafter, when replacing the existing mask with a new mask, after removing the existing mask, the new mask may be coupled to the frame by forming additional welding portions without a process of removing the welding portions remaining on the frame. Accordingly, when replacing the mask, the number of times the frame can be reused may be increased, and the cost required for manufacturing a new frame may be reduced.

The mask according to an embodiment of the disclosure may be partially welded on the frame, and the frame may be reused multiple times when replacing the mask. Thus, the cost required for mask replacement may be reduced.

Since the frame according to an embodiment of the disclosure has a recessed portion, the mask may be readily and partially welded on the frame.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A mask replacement method comprising:
providing a mask assembly comprising:
a frame comprising an opening;
a first mask disposed on the frame; and
first welding portions overlapping the first mask in a plan view;
removing the first mask from the frame; and
forming a second mask and second welding portions overlapping the second mask in a plan view on the frame on which the first welding portions are disposed, wherein
the first welding portions are spaced apart from the second mask, and
the first welding portions and the second welding portions are arranged in a direction.

2. The mask replacement method of claim 1, wherein the providing of the mask assembly comprises:
providing, on the frame, a first preliminary mask comprising:
a first deposition portion overlapping the opening in a plan view;
a plurality of first coupling portions protruding from the first deposition portion; and
a plurality of first non-coupling portions protruding from the first deposition portion;
forming the first welding portions in the plurality of first coupling portions to couple the plurality of first coupling portions and the frame to each other; and
removing the plurality of first non-coupling portions from the first preliminary mask to form the first mask.

3. The mask replacement method of claim 2, wherein
the plurality of first coupling portions are spaced apart from each other in the direction, and
at least one of the plurality of first non-coupling portions is disposed between adjacent ones of the plurality of first coupling portions in a plan view.

4. The mask replacement method of claim 2, wherein
the providing of the first preliminary mask comprises:
providing a first initial preliminary mask comprising:
the first deposition portion; and
a first non-deposition portion surrounding the first deposition portion; and
forming first cutting portions passing through the first initial preliminary mask in the first non-deposition portion to form the first preliminary mask,
the first cutting portions are spaced apart from each other in a first direction and a second direction intersecting the first direction in a plan view, and
regions between the first cutting portions respectively correspond to the plurality of first coupling portions and the plurality of first non-coupling portions.

5. The mask replacement method of claim 4, wherein a distance between the first cutting portions is about 2 mm or more.

6. The mask replacement method of claim 4, wherein each of the first cutting portions extends to an outer edge of the first initial preliminary mask.

7. The mask replacement method of claim 4, wherein each of the first cutting portions is surrounded by the first non-deposition portion.

8. The mask replacement method of claim 7, wherein
the providing of the first preliminary mask further comprises cutting at least a portion of the first preliminary mask along a first trimming line defined on the first preliminary mask, and
the first trimming line corresponds to a virtual line connecting inner side surfaces of the first cutting portions adjacent to an outer edge of the first preliminary mask.

9. The mask replacement method of claim 8, wherein
the frame further comprises a first recessed portion recessed from an upper surface on which the first preliminary mask is disposed, and
the first recessed portion overlaps the first trimming line in a plan view.

10. The mask replacement method of claim 2, wherein
the frame further comprises a second recessed portion recessed from an upper surface on which the first preliminary mask is disposed, and
the removing of the plurality of first non-coupling portions includes irradiating a beam onto the first non-coupling portions overlapping the second recessed portion in a plan view.

11. The mask replacement method of claim 1, wherein
the forming of the second mask and the second welding portions comprises:
providing, on the frame, a second preliminary mask comprising:
a second deposition portion overlapping the opening in a plan view;
a plurality of second coupling portions protruding from the second deposition portion; and
a plurality of second non-coupling portions protruding from the second deposition portion;
forming the second welding portions on the plurality of second coupling portions to couple the plurality of second coupling portions and the frame to each other; and
removing the plurality of second non-coupling portions from the second preliminary mask to form the second mask, and
the plurality of second coupling portions respectively non-overlap the first welding portions in a plan view.

12. The mask replacement method of claim 4, wherein
the forming of the second mask comprises providing a second preliminary mask,
the second mask is formed from the second preliminary mask,
the providing of the second preliminary mask comprises:
providing a second initial preliminary mask; and
forming second cutting portions on the second initial preliminary mask,
the first initial preliminary mask and the second initial preliminary mask have a same area and shape, and
the first cutting portions and the second cutting portions have a same position and size.

13. The mask replacement method of claim 1, wherein each of the first welding portions and the second welding portions comprises a metal oxide.

14. The mask replacement method of claim 1, further comprising:
removing the second mask from the frame;
polishing the frame to remove the first welding portions and the second welding portions remaining on the frame; and
forming a third mask and third welding portions overlapping the third mask in a plan view on the frame.

15. A mask assembly comprises:
a frame comprising:
an upper surface;
a lower surface opposite to the upper surface; and
an opening passing through from the upper surface to the lower surface;
a mask disposed on the frame;
first welding portions disposed on the frame; and
second welding portions disposed on the frame,
wherein the mask comprises:
a deposition portion overlapping the opening in a plan view; and
a plurality of coupling portions protruding from the deposition portion and overlapping the frame in a plan view,
the second welding portions respectively overlap the plurality of coupling portions in a plan view, and
each of the first welding portions is spaced apart from the mask.

16. The mask assembly of claim 15, wherein:
each of the frame and the mask comprises a metal, and
each of the first and second welding portions comprises a metal oxide.

17. The mask assembly of claim 15, wherein:
the plurality of coupling portions are spaced apart from each other in a first direction and a second direction intersecting the first direction in a plan view, and
the first welding portions are disposed between the plurality of coupling portions spaced apart from each other.

18. The mask assembly of claim 17, wherein the first welding portions and the second welding portions are arranged in the first direction and the second direction in a plan view.

19. The mask assembly of claim 15, wherein
the frame further comprises:
a first recessed portion recessed from the upper surface; and
a second recessed portion recessed from the upper surface,
in a plan view, the first recessed portion overlaps ends of the deposition portion exposed from the plurality of coupling portions, and
the second recessed portion overlaps ends of the plurality of coupling portions in a plan view.

20. A mask assembly comprises:
a frame comprising:
an upper surface;
a lower surface opposite to the upper surface;
an opening passing through from the upper surface to the lower surface;
a first recessed portion recessed from the upper surface; and
a second recessed portion recessed from the upper surface;
a mask disposed on the frame; and
welding portions disposed on the frame, wherein
the mask comprises:
a deposition portion overlapping the opening in a plan view; and
a plurality of coupling portions protruding from the deposition portion and overlapping the frame in a plan view,
at least some of the welding portions overlap the mask in a plan view,
the first recessed portion overlaps ends of the deposition portion exposed from the plurality of coupling portions in a plan view, and
the second recessed portion overlaps ends of the plurality of coupling portions in a plan view.
